(19) United States
(12) Patent Application Publication
(10) Pub. No.: US 2010/0096117 A1
(43) Pub. Date: Apr. 22, 2010

(54) RADIATOR PLATE, PERFORATED PLATE AND METHODS OF MAKING THE SAME

(75) Inventors: Masahiro SEIDO, Tsuchiura (JP); Kazuhiko Nakagawa, Tsuchiura (JP); Chingping Tong, Tsuchiura (JP)

Correspondence Address: FOLEY AND LARDNER LLP;SUITE 500, 3000 K STREET NW, WASHINGTON, DC, 20007, US

(73) Assignee: HITACHI CABLE, LTD.

(21) Appl. No.: 12/580,470

(22) Filed: Oct. 16, 2009

(30) Foreign Application Priority Data
Oct. 17, 2008 (JP) 2008-269192
Oct. 17, 2008 (JP) 2008-269193

(51) Int. Cl. H01L 23/36; F28F 7/00; B21D 53/02

(52) U.S. Cl. 165/185; 29/890.03

(57) ABSTRACT

A radiator plate includes a core having core surfaces and holes whose hole axes are directed in a direction along a normal direction of the core surface, and heat transfer plates joined to the core surfaces and filled in the holes. A multilayer radiator plate includes a first radiator plate including a first core having first core surfaces and first holes whose hole axes are directed in a direction along a normal direction of the first core surface and first heat transfer plates joined to the first core surfaces and filled in the first holes, a second radiator plate including a second core having second core surfaces and second holes whose hole axes are directed in a direction along a normal direction of the second core surface and second heat transfer plates joined to the second core surfaces and filled in the second holes, and the first radiator plate and the second radiator plate are joined to each other.

The present application is based on Japanese patent application Nos. 2008-269192 and 2008-269193, the entire contents of which are incorporated herein by reference.

### BACKGROUND OF THE INVENTION

1. Field of the Invention

This invention relates to a radiator plate, a multilayer radiator plate for mounting a semiconductor device thereon and a method of making the radiator plate.

Also, this invention relates to a perforated plate with fine holes therein and a method of making the perforated plate.

2. Description of the Related Art

A semiconductor device to be mounted on a circuit board used for an industrial machine tool, an industrial robot, a compressor of an air conditioner, a semiconductor manufacturing equipment, a medical equipment, a motor drive of a hybrid car or the like may be supplied with large current of not less than 100 A. In this case, a temperature of the semiconductor device supplied with current may become to not less than 100 degrees C. due to heat generation. Heat emitted from the semiconductor device seriously affects reliability and lifetime of each part mounted on the circuit board including the semiconductor device. Consequently, in order to radiate the heat emitted from the semiconductor device, a circuit board including a base member, a heat spreader, a heat sink and the like as the circuit board mounting the semiconductor device is known. Further, a circuit board using a composite material for radiation is also known.

A composite material is known as a conventional composite material for radiation, that includes an expanded metal formed of a metal plate having a linear heat expansion coefficient of not more than 8×10⁻⁶/degrees C. and a matrix metal formed of copper (Cu) encompassing the expanded metal. This technique is disclosed in, for example, JP-A-2003-152144. Further, a shape of the expanded metal is set forth in Japanese Industrial Standards (JIS) G3351 (Expanded Metals).

The composite material according to JP-A-2003-152144 can realize a low linear heat expansion coefficient by the expanded metal and simultaneously ensure a good heat conductivity due to the matrix metal, so that a composite material excellent in strength and heat conductivity can be provided. Further, the expanded metal is encompassed with the matrix metal so that the production cost can be reduced in comparison with a case that the holes are formed in a flat plate-like metal plate by a precise casting method, a punching or the like.

However, the composite material according to JP-A-2003-152144 uses an expanded metal having such large holes as the ratio of the hole diameter to the plate thickness is 10 times to 100 times, and conventional expanded metals have a tendency that the hole axes are inclined to the plate surface and an opening ratio is lowered in case that the ratio of the hole diameter to the plate thickness is set to less than 10 times, so that it is difficult to manufacture a composite material having a good heat-transfer property while maintaining small hole diameters.

On the other hand, an expanded metal is known as a conventional expanded metal, the expanded metal being obtained by forming a plurality of cuts to a metal plate in a staggered shape and simultaneously expanding the cuts by an expanded metal manufacturing machine, obtaining an expanded metal having a mesh-like shape by forming the expanded cuts to a diamond shape or a tortoiseshell shape, and applying a flat work to the expanded metal of mesh-like shape. This technique is disclosed in, for example, Suzuki Technos Co., LTD, “Expanded metal” searched on Jul. 20, 2008 (H20) by Internets (URL: http://www.suzuki-tkns. Co.jp/product/expanded/index.html).

However, since the expanded metal disclosed in the Internet is only an expanded metal obtained by applying a rolling work to an expanded metal to which the flat work is not applied, the hole axes of the holes included in the expanded metal can not be perpendicular to the plate surface and it is difficult to enlarge uses of the perforated plate.

### SUMMARY OF THE INVENTION

Therefore, it is an object of the invention to provide a radiator plate and a multilayer radiator plate that are capable of enhancing a heat conductivity (or thermal conductivity coefficient) in a direction of the plate thickness and a method of making the radiator plate.

And, it is another object of the invention to solve the above-mentioned problem and provide a method of making a perforated plate having hole axes perpendicular to the plate surface and the perforated plate.
(1) According to one embodiment of the invention, a radiator plate comprises:

a core having core surfaces and holes whose hole axes are directed in a direction along a normal direction of the core surface; and

heat transfer plates joined to the core surfaces and filled in the holes.

In the above embodiment (1), the following modifications and changes can be made.

(i) The holes are formed by being enclosed with a plurality of strands,

the core surfaces include a first core surface formed by one surface of the plural strands and a second core surface formed by another surface of the plural strands and opposed to the first core surface, and

the hole axes are directed in directions along normal directions of the first core surface and the second core surface.

(ii) The heat transfer plates include a first heat transfer plate disposed so as to contact the first core surface and a second heat transfer plate disposed so as to contact the second core surface, and

the first heat transfer plate and the second heat transfer plate are connected to each other via the first heat transfer plate filled in the holes and the second heat transfer plate filled in the holes.

(iii) The core has a plurality of the holes, and

a ratio of a distance between one hole of the plural holes and another hole adjacent to the one hole to a plate thickness of the heat transfer plate is less than 10.

(iv) The plural holes have total areas on a plan view whose occupation ratio to a surface area of the heat transfer plate is not less than 10% and not more than 90%.

(v) The core is formed of a material having a heat expansion coefficient lower than the heat transfer plate, and

the heat transfer plate is formed of a material having a thermal conductivity coefficient higher than the core.

(vi) The core is formed of an Invar material or a super Invar material, and

the heat transfer plate is formed of a material selected from the group consisting of copper (Cu), aluminum (Al), a copper alloy and an aluminum alloy.
(2) According to another embodiment of the invention, a multilayer radiator plate comprises:

a first radiator plate including a first core having first core surfaces and first holes whose hole axes are directed in a direction along a normal direction of the first core surface and first heat transfer plates joined to the first core surfaces and filled in the first holes;

a second radiator plate including a second core having second core surfaces and second holes whose hole axes are directed in a direction along a normal direction of the second core surface and second heat transfer plates joined to the second core surfaces and filled in the second holes; and

the first radiator plate and the second radiator plate are joined to each other.
(3) According to another embodiment of the invention, a method of making a radiator plate comprises:

preparing a core material having core surfaces and holes whose hole axes are directed in a direction along a normal direction of the core surface; and

joining heat transfer plates to the surfaces of the core material.

In the above embodiment (3), the following modifications and changes can be made.

(vii) The preparing of the core material comprises:

forming a plurality of cuts in a flat plate by pressing a press forming part to the flat plate intermittently-fed, in a direction of a lower cutter supporting the flat plate at the one surface of the flat plate, from another surface side of the flat plate;

forming a shaped article having a plurality of oblique holes and a flat surface by applying a press forming to the plural cuts; and

applying a compression forming to the shaped article along a direction of the hole axes of the plural oblique holes of the shaped article so as to form the core surface having the plural holes whose hole axes are perpendicular to a direction of the flat surface of the shaped article and being perpendicular to a direction to which the hole axes face.

(viii) The lower cutter has cutting edges for forming the plural cuts and a forming mold part disposed adjacent to the cutting edges for applying a press work to the plural cuts,

the plural cuts are formed by that the press forming part is pressed toward the cutting edges, and

the shaped article are formed together in forming the cuts by that the press forming part is pressed toward the forming mold part.

(ix) The method further comprises:

correcting a direction of the hole axes by applying a bending work to the shaped article; and

forming the radiator plate from the shaped article to which the bending work is applied.

(x) The plural cuts are formed to the flat plate that is fed in a state of being inclined to a longitudinal direction of the lower edges, and simultaneously at a feeding stroke synchronized with a cycle when the press forming part is pressed to the flat plate.

(xi) The heat transfer plates are joined to each other by using a cold rolling clad process or a warm rolling clad process.
(4) According to another embodiment of the invention, a method of making a perforated plate comprises:

forming a plurality of cuts in a flat plate by pressing a press forming part to the flat plate intermittently-fed, in a direction of a lower cutter supporting the flat plate at the one surface of the flat plate, from another surface side of the flat plate;

forming a shaped article having a plurality of oblique holes and a flat surface by applying a press forming to the plural cuts; and

applying a compression forming to the shaped article along a direction of the hole axes of the plural oblique holes of the shaped article so as to form the perforated plate having the plural holes whose hole axes are perpendicular to a direction of the flat surface of the shaped article and being perpendicular to a direction to which the hole axes face.

In the above embodiment (4), the following modifications and changes can be made.

(xii) The lower cutter has cutting edges for forming the plural cuts and a forming mold part disposed adjacent to the cutting edges for applying a press work to the plural cuts,

the plural cuts are formed by that the press forming part is pressed toward the cutting edges, and

the shaped article are formed together in forming the cuts by that the press forming part is pressed toward the forming mold part.

(xiii) The method further comprises:

applying a bending work to the shaped article; and

forming the perforated plate from the shaped article to which the bending work is applied.

(xiv) The plural cuts are formed to the flat plate that is fed in a state of being inclined to a longitudinal direction of the lower edges, and simultaneously at a feeding stroke synchronized with a cycle when the press forming part is pressed to the flat plate.

(xv) Where a distance between one hole of the plural holes and another hole adjacent to the one hole is defined as LW and a plate thickness of the perforated plate is defined as W, the perforated plate is formed so as to have a value of the LW which is not less than a value of the W.
(5) According to another embodiment of the invention, a method of making a perforated plate includes:

forming a plurality of cuts in a flat plate by pressing a press forming part to the flat plate intermittently-fed, in a direction of a lower cutter supporting the flat plate at the one surface of the flat plate, from another surface side of the flat plate;

forming a shaped article having a plurality of oblique holes and a flat surface by applying a press forming to the plural cuts; and

applying a compression forming to the shaped article along a direction of the hole axes of the plural oblique holes of the shaped article by pressing a smoothing compression press part to the shaped article from a direction perpendicular to the pressing direction of the press forming part so as to form the perforated plate having the plural holes whose hole axes are perpendicular to a direction of the flat surface of the shaped article and being perpendicular to a direction to which the hole axes face.

In the above embodiment (5), the following modifications and changes can be made.

(xvi) The smoothing compression press part is pressed to a side surface of the lower cutter.
(6) According to another embodiment of the invention, a perforated plate comprises:

a plurality of strands;

a plurality of holes formed by being encompassed with the plural strands; and

core surfaces formed by surfaces of the plural strands, wherein hole axes of the plural holes are perpendicular to the core surfaces.

In the above embodiment (6), the following modifications and changes can be made.

(xvii) Where a distance between one hole of the plural holes and another hole adjacent to the one hole is defined as LW and a plate thickness of the perforated plate is defined as W, a value of the LW is not less than a value of the W.

### POINTS OF THE INVENTION

According to one embodiment of the invention, a radiator plate is constructed such that a core includes a plurality of holes having a fine diameter similar to the plate thickness of the core, the hole axes of the plural holes included in the core are directed to a perpendicular direction to a surface of the radiator plate and simultaneously, an opening ratio can be heightened, so that a first heat transfer plate and a second heat transfer plate can be appropriately joined to each other in the plural holes. Thus, by forming the holes of the embodiment, a region where materials constituting the first heat transfer plate and the second heat transfer plate are joined to each other can be increased and the penetration ratio can be increased. Therefore, the radiator plate can have good heat conductivity in the plate thickness direction.

According to another embodiment of the invention, a method of making a perforated plate is composed such that a cutting process and a press process being a precise press process are simultaneously applied to a flat plate fed to a perforated plate production equipment, and after that, a bending work and a compression process are applied, so that the perforated plate (fine perforated plate, namely, fine pore metal) that is smooth and has holes whose hole axes are perpendicular to core surfaces, whose hole diameter is smaller than the plate thickness and whose opening ratio is large can be provided.

### BRIEF DESCRIPTION OF THE DRAWINGS

The preferred embodiments of the invention will be explained below referring to the drawings.

FIG. 1A is a plan view schematically showing a radiator plate according to a first embodiment;

FIG. 1B is a cross-sectional view taken along the line A-A in FIG. 1A;

FIG. 2A is an explanatory view schematically showing a part of a making process of the radiator plate according to the first embodiment;

FIG. 2B is a perspective view schematically showing a structure just before the making of the radiator plate according to the first embodiment;

FIG. 3A is a plan view schematically showing a core material used for the first embodiment;

FIG. 3B is a cross-sectional view taken along the line B-B in FIG. 3A;

FIG. 4A is a partial enlarged view schematically showing a hole of the core material used for the first embodiment;

FIG. 4B is a cross-sectional view taken along the line b-b in FIG. 4A;

FIG. 5A is a cross-sectional view schematically showing a method of making the core material used for the first embodiment;

FIG. 5B is a cross-sectional view schematically showing a method of making the core material used for the first embodiment;

FIG. 5C is an explanatory view schematically showing a flow of a raw material used for making the core material used for the first embodiment;

FIG. 5D is a perspective view schematically showing a lower cutter used for making the core material used for the first embodiment;

FIG. 6 is a graph schematically showing a relationship between a heat conductivity and a heat expansion coefficient of the radiator plate according to the first embodiment;

FIG. 7 is a cross-sectional view schematically showing a core material making equipment used for a second embodiment;

FIG. 8 is a cross-sectional view schematically showing a multilayer radiator plate according to a third embodiment;

FIG. 9 is a graph schematically showing a heat conductivity in a plate thickness direction and a ratio of through hole pitch to plate thickness of the radiator plate according to Examples and Comparative Examples;

FIG. 10 is a graph schematically showing a heat expansion coefficient of the radiator plate according to Examples and Comparative Examples;

FIG. 11A is a plan view schematically showing a part of perforated plate according to a fourth embodiment;

FIG. 11B is a cross-sectional view taken along the line A-A in FIG. 11A;

FIG. 12A is a partial enlarged view schematically showing a hole of the perforated plate according to the fourth embodiment;

FIG. 12B is a cross-sectional view taken along the line b-b in FIG. 12A;

FIG. 13A is a cross-sectional view schematically showing a top dead point position of press in a method of making the perforated plate according to the fourth embodiment;

FIG. 13B is a cross-sectional view schematically showing a bottom dead point position of press in a method of making the perforated plate according to the fourth embodiment;

FIG. 13C is an explanatory view schematically showing a flow of a raw material used for making the perforated plate according to the fourth embodiment;

FIG. 13D is a perspective view schematically showing a lower cutter used for making the perforated plate according to the fourth embodiment;

FIG. 14 is a cross-sectional view schematically showing a perforated plate making equipment used for a fifth embodiment;

FIG. 15A is an explanatory view schematically showing each site of a shaped article before a cutting process (a process of forming cuts) and a press work process in Example 5 and Examples 6 to 11;

FIG. 15B is an explanatory view schematically showing each site of a shaped article after the cutting process (process of forming cuts) and the press work process in Example 5 and Examples 6 to 11;

FIG. 16 is a graph showing a compassion result of an opening ratio and a hole axis inclination between a perforated plate according to Example 5 and expanded metals according to Comparative Examples 6 and 7;

FIG. 17 is a graph showing a compassion result of an opening ratio and a hole axis inclination between a perforated plate according to Example 6 and expanded metals according to Comparative Examples 8 and 9;

FIG. 18 is a graph showing a compassion result of an opening ratio and a hole axis inclination between a perforated plate according to Example 7 and expanded metals according to Reference Examples 1 and 2;

FIG. 19A is an explanatory view schematically showing a perforated plate according to Reference Example 1;

FIG. 19B is an explanatory view schematically showing a perforated plate according to Reference Example 2; and

FIG. 19C is an explanatory view schematically showing a perforated plate having a structure of a fine pore metal according to Example 7.

### DETAILED DESCRIPTION OF THE PREFERRED EMBODIMENTS

The preferred embodiments according to the invention will be explained below referring to the drawings.

### First Embodiment

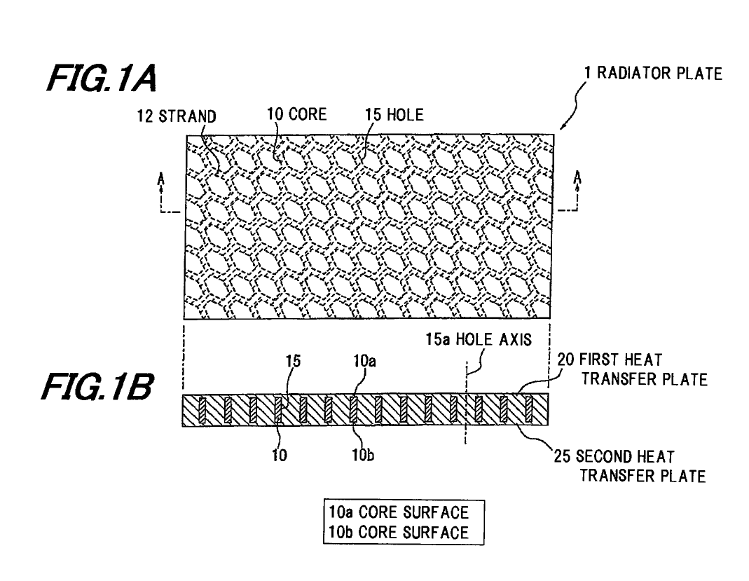

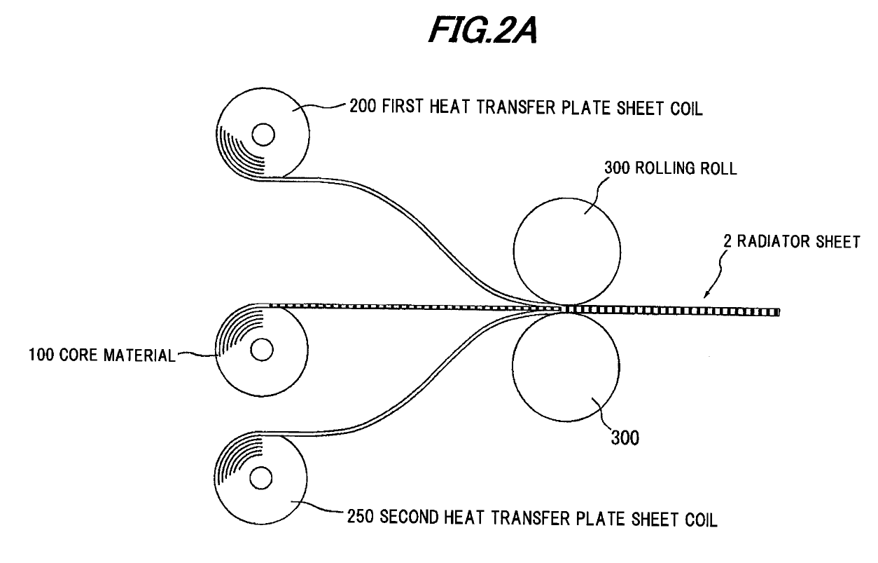

FIG. 1A is a plan view schematically showing a radiator plate according to a first embodiment and FIG. 1B is a cross-sectional view taken along the line A-A in FIG. 1A.

Structure of Radiator Plate 1

A radiator plate 1 according to a first embodiment of the invention includes a core 10 having holes 15 formed by being encompassed with a plurality of strands 12, a first heat transfer plate 20 disposed so as to be joined to an upper surface of the core 10 and a second heat transfer plate 25 disposed so as to be joined to a lower surface of the core 10.

The radiator plate 1 according to the embodiment is formed, for example, so as to have a plate thickness (TIT) of almost not less than 0.1 mm and not more than 1 mm. And, a pitch of the hole 15 used for the embodiment, namely, a distance between one hole 15 and another hole adjacent to the one hole 15 (hereinafter referred to as “through hole pitch (LW)”) is formed, for example, so as to be almost not less than 0.1 mm and not more than 3 mm. Further, the radiator plate 1 according to the embodiment has a through hole pitch (LW) and a plate thickness (TIT) such that a ratio (LW/TIT) of the plate thickness (TIT) and the through hole pitch (LW) becomes less than 10. And, an occupation ratio of total areas on a plan view of the plural holes 15 included in the radiator plate 1 to a surface area on a plan view of the radiator plate 1 can be not less than 10% and not more than 90%.

Core 10

The core 10 includes a core surface 10a as a first core surface joined to a part of a surface of the first heat transfer plate 20 and a core surface 10b as a second core surface joined to a part of a surface of the second heat transfer plate 25. The core surface 10a is a surface formed by one surface of the plural strands 12 and the core surface 10b is a surface formed by another surface of the plural strands 12. Namely, the core surface 10a and the core surface 10b are located oppositely. And, hole axes 15a of the holes 15, the holes 15 being micropores included in the core 10, are directed to a direction perpendicular to the core surface 10a and the core surface 10b. Namely, hole axes are directed to directions along normal directions of the core surfaces 10a and 10b.

Further, the core 10 includes the plural holes 15, and an each inside of the holes 15 is filled by a material constituting the first heat transfer plate 20 and a material constituting the second heat transfer plate 25. Particularly, the first heat transfer plate 20 and the second heat transfer plate 25 are connected to each other by that the first heat transfer plate 20 and the second heat transfer plate 25 are joined to each other in the hole 15. Consequently, in the embodiment, the radiator plate 1 is integrally formed by the core 10, the first heat transfer plate 20 and the second heat transfer plate 25.

And, the core 10 is formed of a material having a heat expansion coefficient lower than materials which constitute the first heat transfer plate 20 and second heat transfer plate 25. For example, the core 10 is formed of an Invar material or a super Invar material which is a low heat expansion coefficient material that has a low heat expansion coefficient in a usual temperature range. The Invar material is, as an example, a Fe-36Ni alloy which includes 36 mass % of nickel (Ni) and iron (Fe) as the residue. And, the super Invar material is, as an example, a Fe-32Ni-5Co alloy which includes 32 mass % of nickel (Ni), and 5 mass % of cobalt (Co) and iron (Fe) as the residue.

First Heat Transfer Plate 20 and Second Heat Transfer Plate 25

The first heat transfer plate 20 and the second heat transfer plate 25 are respectively formed of a material having a thermal conductivity coefficient higher than a material which constitutes the core 10. Particularly, the first heat transfer plate 20 and the second heat transfer plate 25 are respectively formed of copper (Cu), aluminum (Al), a copper alloy or an aluminum alloy. Further, the material constituting the first heat transfer plate 20 and the material constituting the second heat transfer plate 25 can be the same material or a different material. Further, the first heat transfer plate 20 and the second heat transfer plate 25 can be respectively formed of silver (Ag) having a thermal conductivity coefficient higher than copper (Cu). Furthermore, the first heat transfer plate 20 and the second heat transfer plate 25 can be respectively formed of carbon (C) which has a large anisotropy and an in-plane thermal conductivity coefficient higher than copper (Cu).

Method of Making Radiator Plate 1

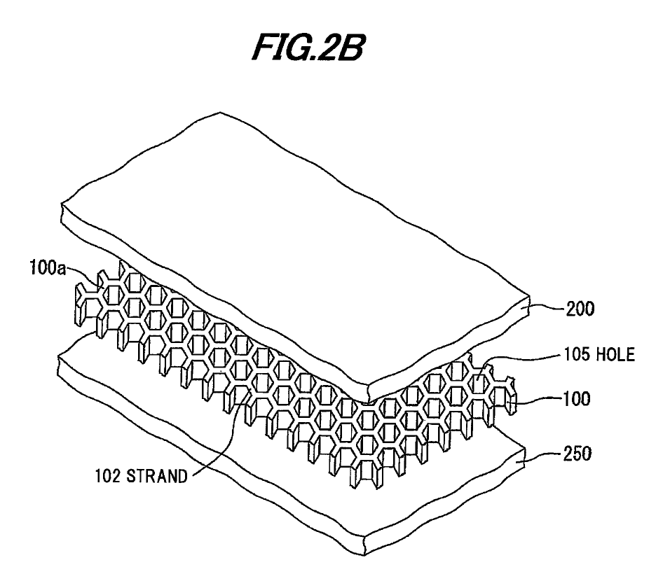

FIG. 2A is an explanatory view schematically showing a part of a making process of the radiator plate according to the first embodiment, and FIG. 2B is a perspective view schematically showing a structure just before the making of the radiator plate according to the first embodiment.

First, FIG. 2A is referred. A first heat transfer plate sheet coil 200 composed of a material to be formed to the first heat transfer plate 20, a second heat transfer plate sheet coil 250 composed of a material to be formed to the second heat transfer plate 25, and a coil formed by that a core material 100 to be formed to the core 10 is wound are prepared. And, a sheet for the first heat transfer plate and a sheet for the second heat transfer plate are pulled out from the first heat transfer plate sheet coil 200 and the second heat transfer plate sheet coil 250, and simultaneously, the core material 100 is also pulled out. Next, the first heat transfer plate sheet is laminated on one surface of the core material 100 and simultaneously the second heat transfer plate sheet is laminated on another surface of the core material 100 by rolling rolls 300. By this, a radiator sheet 2 is manufactured. And, the radiator sheet 2 manufactured is cut out into a predetermined shape, so that the radiator plate 1 according to the first embodiment is manufactured.

Further, a surface treatment can be applied to the one surface and the other surface of the core material 100. For example, fine concavity and convexity are formed on the one surface and the other surface of the core material 100 by using a wire brush or the like. By this, newborn surfaces are formed on the one surface and the other surface of the core material 100, so that bonding capability between the core material 100 and the first and second heat transfer plate sheets can be enhanced.

Here, as the rolling by the rolling roll 300, a cold rolling clad process or a warm rolling clad process is adopted. In total, a reduction draft of not less than 40% and not more than 55% is added to the core material 100 sandwiched between the sheet pulled out from the first heat transfer plate sheet coil and the sheet pulled out from the second heat transfer plate sheet coil. By the rolling, a material constituting the sheet pulled out from the first heat transfer plate sheet coil and a material constituting the sheet pulled out from the second heat transfer plate sheet coil are fluidly moved and intruded into holes 105 formed by being encompassed with a plurality of strands 102 included in the core material 100, and simultaneously, both of the materials are joined to each other in the holes 105. Further, the joined part has a somewhat low reduction but it is a part largely changed in shape, so that newborn surfaces of both the materials appear and both the materials are joined at the newborn surfaces together. And, both the materials and the surface of the core material 100 are joined to each other. Subsequently, after the rolling by the rolling roll 300, a diffusion heat treatment is carried out under a predetermined atmosphere, at a temperature of not less than 600 degrees C. and not more than 800 degrees C. so that the radiator sheet 2 is manufactured. The diffusion heat treatment is carried out, so that dissimilar metals (namely, a metal constituting both the materials and a metal constituting the core material 100) are mixed with each other at the place between both the materials and the core material 100, and bonding capability between the both the materials and the core material 100 can be enhanced. Namely, the diffusion heat treatment is carried out, so that a diffusion bonding is advanced between the both the materials and the core material 100.

FIG. 2B shows a positional relationship among the sheet pulled out from the first heat transfer plate sheet coil, the sheet pulled out from the second heat transfer plate sheet coil, and the core material 100 before being rolled by the rolling roll 300. Namely, the core material 100 is located at a position that it is sandwiched between the sheet pulled out from the first heat transfer plate sheet coil 200 and the sheet pulled out from the second heat transfer plate sheet coil 250. And, by the rolling roll 300, a core surface 100a and the sheet pulled out from the first heat transfer plate sheet coil 200 are joined to each other, and simultaneously, a core surface located oppositely to the core surface 100a and the sheet pulled out from the second heat transfer plate sheet coil 250 are joined to each other, so that the radiator sheet 2 is formed.

Details of Core Material 100

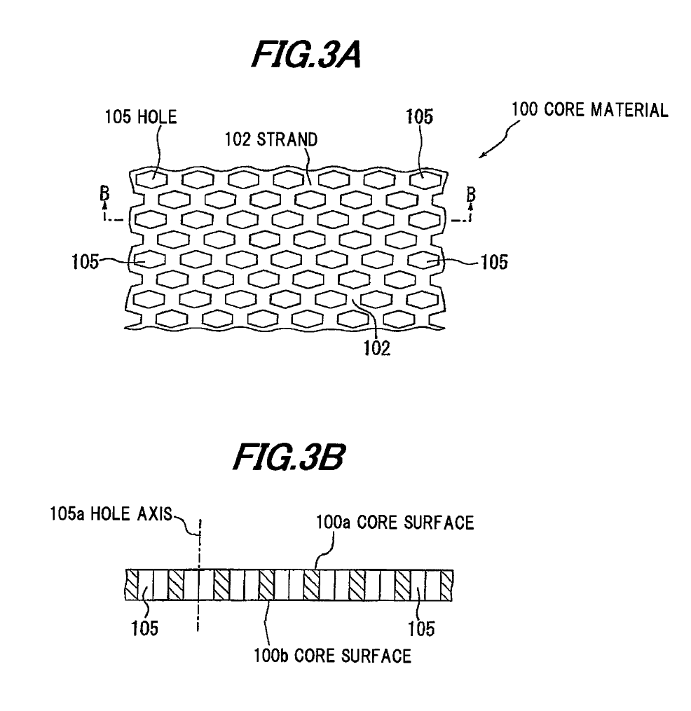

FIG. 3A is a plan view schematically showing a core material used for the first embodiment, and FIG. 3B is a cross-sectional view taken along the line B-B in FIG. 3A.

The core material 100 includes a plurality of strands 102 and holes 105 formed by being encompassed with the strands 102. The plural strands 102 forming one hole 105 are sequentially and integrally formed. And, a core surface 100a and a core surface 100b located oppositely to the core surface 100a are formed by the surfaces of the plural strands 102. Further, the holes 105 are formed so that the hole axes 105a become perpendicular to the core surface 100a and the core surface 100b. Namely, a direction to which the hole axes 105a are directed corresponds with a normal direction of the core surface 100a and a normal direction of the core surface 100b.

The plural holes 105 included in the core material 100 are formed so as to have an arrangement that a pattern is repeated where one hole 105 is encompassed with other six holes 105 adjacent to the one hole 105. Particularly, the plural holes 105 are formed in a honeycomb shape. The plural holes 105 are respectively formed in almost a hexagonal shape (or a tortoiseshell shape) on a plan view. Further, in a modification of the embodiment, the plural holes 105 can also be formed in a tetragonal shape on a plan view respectively. In the embodiment, the core material 100 having an opening ratio of, for example, not less than 65% is used.

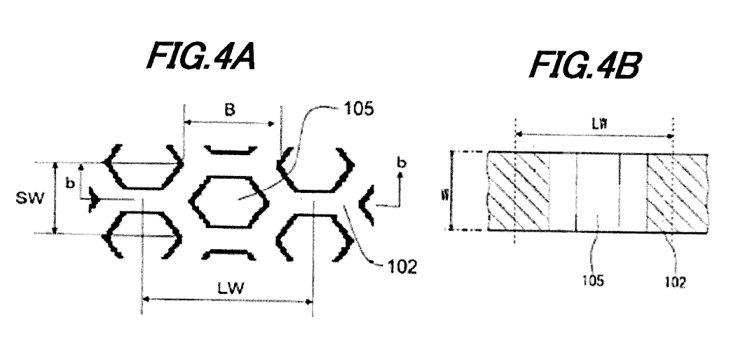

FIG. 4A is a partial enlarged view schematically showing a hole of the core material used for the first embodiment, and FIG. 4B is a cross-sectional view taken along the line b-b in FIG. 4A.

In FIG. 4A, a distance between one hole 105 and another hole adjacent to the one hole 105 (hereinafter referred to as “hole pitch of first direction” or “hole pitch of direction along a width of cutting edge 52” described below) is defined as LW. And, a plate thickness of the core material 100 is defined as W. In this case, in the core material 100 used for the embodiment, a value of LW is formed so as to be not less than that of W. Further, in FIG. 4B, T represents a plate thickness of a flat plate which is a raw material of the core material 100. And, a hole pitch of second direction, namely, a hole pitch of a direction perpendicular to the first direction (direction along a width of cutting edge 52) is defined as SW. Further, B represents a bond length. Here, the core material 100 used for the embodiment has a shape that, for example, a value of LW is not less than a value of W. For example, the core material 100 can be formed so as to have a ratio (LW/W) between LW and W of not more than 3, preferably not less than 1 and not more than 3. And, as an example, a flat plate having a plate thickness T of not more than 1 mm can be used, in order that the plate thickness W is reduced to a value being not more than a size of the hole 105.

Method of Making Core Material 100

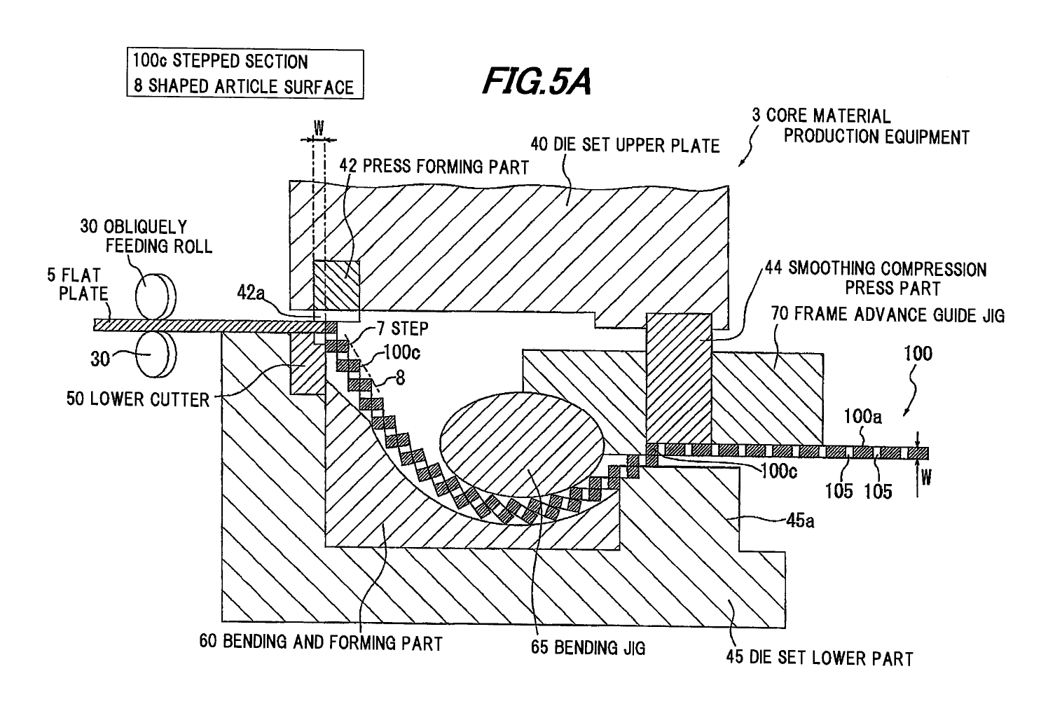

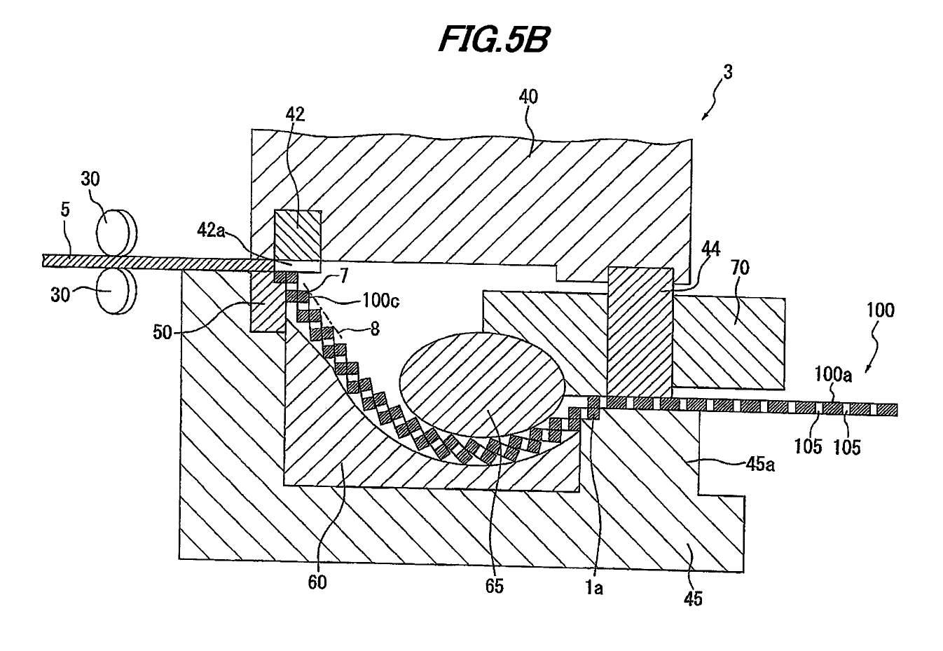

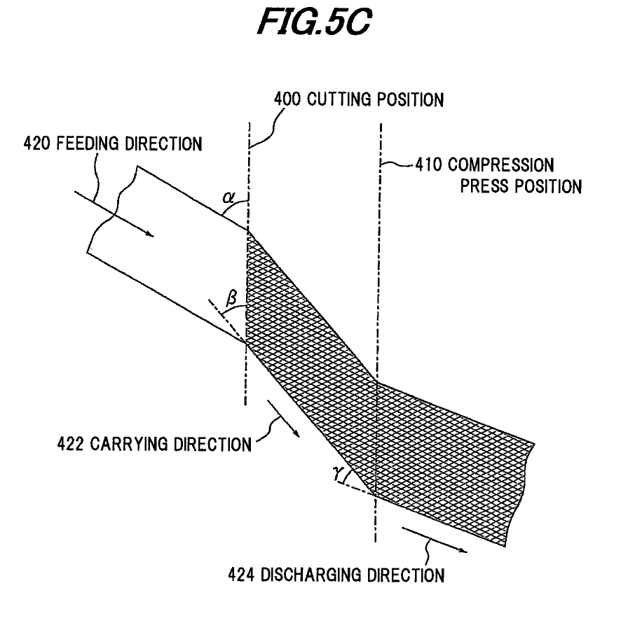

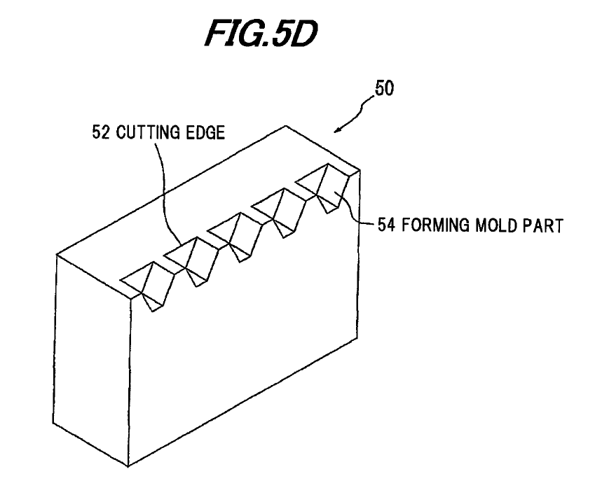

FIGS. 5A and 5B are cross-sectional views schematically showing a method of making the core material used for the first embodiment, FIG. 5C is an explanatory view schematically showing a flow of a raw material used for making the core material used for the first embodiment and FIG. 5D is a perspective view schematically showing a lower cutter used for making the core material used for the first embodiment.

Particularly, FIG. 5A shows an outline at a top dead point position and just before a press forming process. And, FIG. 5B shows an outline at a bottom dead point position, a shaped article just after the press forming process, and the core material 100 manufactured by passing through a compression process.

A core material production equipment 3 used for making the core material 100 used for the embodiment includes, as shown in FIG. 5A, an obliquely feeding roll 30 for feeding a flat plate 5 which is a material of the core material 100 to the core material production equipment 3, a press forming part 42 and a lower cutter 50 for applying a cut work and a press work to the flat plate 5 which is fed, a bending and forming part 60 and a bending jig 65 for applying a bending work to the shaped article to which the cut work and the press work are applied, a smoothing compression press 44 for applying a compression forming to the shaped article to which the bending work is applied, and a frame advance guide jig 70 for feeding the shaped article to which the bending work is applied to the smoothing compression press 44. Further, the press forming part 42 and the smoothing compression press 44 are held in a die set upper plate 40 and the lower cutter 50 and the bending and forming part 60 are disposed in a die set lower part 45.

In the embodiment, the press forming part 42 and smoothing compression press 44 operate in a normal direction (namely, in a vertical direction) of a surface of the flat plate 5 fed to the core material production equipment 3 according to an operation of the die set upper plate 40. Particularly, the press forming part 42 used for the embodiment moves only in a vertical direction, and does not move in a feeding direction of the flat plate 5 to the core material production equipment 3 and in a perpendicular direction (a normal direction of a plane of paper in FIG. 5A) to both of the vertical direction and the feeding direction.

The core material production equipment 3 intermittently presses the die set upper plate 40 to the die set lower part 45 at high speed so as to apply a cut work, a press work and a smoothing compression work to the flat plate 5, and manufacture the core material 100 used for the embodiment. Hereinafter, the embodiment will be explained in concrete. Further, in the following explanation, the core material 100 used for the embodiment may be referred to as “fine pore metal”.

Flat Plate Feeding Process

First, the flat plate 5 (for example, a solid flat plate coil) which is a material of the core material 100 is inclined to a longitudinal direction of the lower cutter 50 via the obliquely feeding roll 30, and is intermittently fed to the press forming part 42 and the lower cutter 50. Particularly, as shown in FIG. 5C, the longitudinal direction of the flat plate 5 is inclined to a cutting position 400 described below by an angle α where a plurality of cuts are formed by the press forming part 42 and the lower cutter 50, and the flat plate 5 is fed to the core material production equipment 3. Namely, the flat plate 5 is fed to the core material production equipment 3 along a feeding direction 420 which is inclined to the cutting position 400 by an angle α (FIG. 5C). Further, the flat plate 5 is fed to the core material production equipment 3 at a feeding stroke synchronized with a cycle (hereinafter referred to as “cutting cycle”) when the press forming part 42 is pressed to one surface of the flat plate 5.

Here, the angle α is set as an angle that is calculated from the following formula 1.

$$α = {tan}^{- 1} \frac{2 W}{LW} \qquad Formula 1$$

Further, a speed (a feeding speed) for feeding the flat plate 5 to the core material production equipment 3 is set as a speed defined by the following formula per one stroke of the press. Namely, in the embodiment, the feeding speed is synchronized with the cutting cycle. Further, the term “press” means that the press forming part 42 is pressed to the lower cutter 50 so as to cut a part of the flat plate 5, and when the press forming part 42 is pressed to the lower cutter 50, the feeding speed of the flat plate 5 to the core material production equipment 3 becomes zero, and when the press forming part 42 is separated from the lower cutter 50, the feeding speed of the flat plate 5 to the core material production equipment 3 becomes a speed defined by the following formula 2.

$$feeding speed = \sqrt{\frac{{W}^{2} + {LW}^{2}}{4}} \qquad Formula 2$$

Further, in the formulae 1 and 2, “W” represents a feeding width per one stroke of the flat plate 5 in case of feeding the flat plate 5 to the core material production equipment 3. Namely, as shown in FIG. 5A, a cut is formed in the flat plate 5 with respect to each “W”, and “W” corresponds to a step size of the flat plate 5.

Cutting Process and Press Work Process

Next, the flat plate 5 fed between the press forming part 42 and the lower cutter 50 is supported at one surface thereof by the lower cutter 50, and is pressed from a side of another surface thereof by the press forming part 42 (FIG. 5B). By this, a plurality of cuts are formed in the flat plate 5 (cutting process). And, at the same time of the formation of the cuts, the press forming part 42 applies a press work to the plural cuts so as to form shaped articles having a plurality of oblique holes from the plural cuts (press work process). Tangent lines at the corner parts of a plurality of steps 7 of the shaped article form a shaped article surface 8. Further, in the embodiment, the term “oblique hole” means a hole whose hole axis is inclined to a surface of the shaped article. And, the term “at the same time” means “in a series” or “successively”.

And, in a modification of the embodiment, the cutting process and press work process can be carried out as follows. Namely, first, in the cutting process a plurality of cuts are formed in the flat plate 5. And at the time point when the plural cuts are formed, the manufacturing process is once stopped (stopping process). Subsequently, the press work process can be carried out. And, in another modification of the embodiment, the cutting process can be a process that includes a multiple-stage cutting operation.

Particularly, the press forming part 42 used for the embodiment includes a wave edge 42a having a corrugated shape. On the other hand, the lower cutter 50, as shown in FIG. 5D, includes a cutting edge 52 for forming the plural cuts to the flat plate 5 and a forming mold part 54 disposed adjacent to the cutting edge 52 and having an almost corrugated shape, for applying the press work to each of the plural cuts. Namely, an upper end of the lower cutter 50 has a shape that the cutting edge 52 and the forming mold part 54 are successively disposed.

The cutting process and press work process will be explained in more detail. First, the flat plate 5 fed between the press forming part 42 and the lower cutter 50 is formed so as to have intermittent and plural cuts by the wave edge 42a of the press forming part 42 and the cutting edge 52 of the lower cutter 50 (for example, the cuts having a staggered shape are formed in the flat plate 5). Namely, the wave edge 42a is pressed to the cutting edge 52 so that the plural cuts are formed in the flat plate 5. And, a precise press work (for example, a precise wave shape work) are applied to each of the plural cuts by the press forming part 42 and a precise forming mold part which is the forming mold part 54. Namely, the wave edge 42a is pressed to the forming mold part 54 so that an oblique hole is formed in the staggered shape from each of the plural cuts. By this, a shaped article having the oblique holes which are arranged at a short pitch to a plate thickness of the flat plate 5. As an example, a ratio of the plate thickness of the flat plate 5 to the pitch can be set to 2 to 3, and in this case, the pitch can be brought close to the plate thickness. The shaped article where the oblique holes are formed is carried from the press forming part 42 and the lower cutter 50 to an oblique direction to an operation direction of the press forming part 42. Further, a hole pitch of a direction along a width of the cutting edge 52 and a hole pitch of a direction perpendicular to the direction along the width of the cutting edge 52 are almost the same as the pitch of the concavity and convexity of the cutting edge 52 in case of just after the cutting process, and are different from the pitch of the concavity and convexity of the cutting edge 52 in case of after the press process.

The lower cutter 50 used for the embodiment has the cutting edge 52 and the forming mold part 54 so that the cutting and press works are simultaneously applied to the flat plate 5. After the cutting process and the press work process, the flat plate 5 becomes the shaped article having the plural oblique holes. The shaped article, as shown in FIG. 5C, is fed to the bending and forming part 60 along a carrying direction 422. Namely, in the embodiment, a feeding direction 420 of the flat plate 5 to the core material production equipment 3 is changed to the carrying direction 422 which is a different direction from the feeding direction 420 at the cutting position 400.

Here, as shown in FIG. 5C, the carrying direction 422 is inclined to the cutting position 400 by an angle β. The angle β is defined by the following formula.

$$β = {tan}^{- 1} \frac{SW}{LW} \qquad Formula 3$$

Bending Work Process

Next, the shaped article is passed through between the bending and forming part 60 and the bending jig 65 so as to apply a bending work to the shaped article and correct the hole axis direction of the oblique hole (bending work process). Namely, the bending work is applied to the shaped article which passes through the cutting process and the press work process by the bending and forming part 60 and the bending jig 65 so as to arrange the hole axes of the plural oblique holes in one direction. Particularly, the hole axes of the plural oblique holes are arranged in a direction along an operation direction of a smoothing compression press 44 described below. Namely, the hole axes of the plural oblique holes are gradually rotated to the carrying direction 422 as the shaped article is pressed to the bending and forming part 60 by the bending jig 65 and simultaneously is carried along the carrying direction 422. And, the shaped article where the hole axes of the oblique holes are rotated by almost 90 degrees to the hole axes just after the cutting process and the press work process is fed to the smoothing compression press 44.

Further, the shaped article in a state that directions of the hole axes of the oblique holes are equal to each other is fed to the smoothing compression press 44 by a frame advance guide jig 70. Namely, the shaped article is fed to the smoothing compression press 44 frame by frame. Here, the term “frame” means a unit where the plural oblique holes of the shaped article are linearly arranged in a line.

Compression Process

Next, a compression forming is applied to the shaped article fed to the smoothing compression press 44 by the frame advance guide jig 70 frame by frame, by the smoothing compression press 44 which vertically moves in a direction along the hole axes of the holes of the shaped article, namely, along a direction horizontal to the hole axes (compression process, FIG. 5B). The compression forming is applied to a stepped section 100c of the shaped article which is carried between the smoothing compression press 44 and a receiving part 45a. By this, the core material 100 having a plate thickness of “W” is manufactured. Further, in the embodiment, the plate thickness of “W” of the core material 100 corresponds to a feeding width in case of feeding the flat plate 5 to the press forming part 42 and the lower cutter 50.

Subsequently, the core material 100 where a plurality of holes 105 having hole axes perpendicular to the core surface 100a are formed is discharged to the outside of the core material production equipment 3 along the discharging direction 424 (FIG. 5C). The compression forming is applied to the stepped section 100c, so that the core material 100 discharged from the core material production equipment 3 is formed so as to have the core surface 100a and core surface 100b which are flat. Here, the core surface 100b is a surface that is located oppositely to the core surface 100a. Further, if the core material 100 is discharged from the compression press position 410 that is a position where the smoothing compression press 44 applies the compression forming to the shaped article to the outside of the core material production equipment 3, the discharging direction 424 is changed to the compression press position 410 by an angle γ. Further, the angle γ is changed according to a quality of material of the flat plate 5, a shape of the plural holes 105 or the like.

Modifications

In a modification of the method of making the core material 100 used for the first embodiment, the press forming part 42 can be operated not only in a vertical direction, but also in a normal direction of a plane of paper in FIG. 5A (a lateral direction) with half pitch shift, every time when the press forming part 42 is pressed to the lower cutter 50. In this case, both of the press forming part 42 and the lower cutter 50 are reciprocated in a direction perpendicular to the operation direction of the press forming part 42. Namely, the press work is carried out with half pitch shift of the press forming part 42 to the lower cutter 50 and with half pitch shift of the lower cutter 50 to the press forming part 42. And, a structure of the lower cutter 50 is formed to have a shape capable of corresponding to the operation in a lateral direction of the press forming part 42, so that directions of the plural cuts formed in the flat plate 5 can be adjusted to the direction of the shaped article.

Property of Radiator Plate and Cross-Section Composition

The heat conductivity and the heat expansion coefficient of the radiator plate 1 including the core 10 formed of an Invar material, the first heat transfer plate 20 formed of copper and the second heat transfer plate 25 formed of copper can be calculated from the respective values of heat conductivity and heat expansion coefficient of the core 10, the first heat transfer plate 20 and the second heat transfer plate 25.

First, if the core 10 having no holes 15 (a solid clad material) is used, the heat conductivity of the radiator plate 1 (hereinafter referred to as “Cu/Invar/Cu material (CIC material)”) formed so as to have a structure that copper is joined to surfaces of the core 10 is represented by the following formula 4 in case of a plate surface direction, and is represented by the following formula 5 in case of a plate thickness direction.

λ=λ1·f1+λ2·f1 Formula 4

λm=(λ1·λ2·(π1+π2))/(λ1·π2+λ2·π1) Formula 5

And, in case of the radiator plate 1 according to the first embodiment, the heat conductivity of the radiator plate 1 in the plate thickness direction is represented by the following formula 6.

λ=λ2·η+λm·(1−η) Formula 6

Further, in the formulae 4 to 6, λ1 represents a heat conductivity of the core, and λ2 represents a heat conductivity of copper. And, f1 represents a cross-section ratio of the core (a cross-section ratio of Invar, hereinafter may be referred to as “Invar ratio”), and f2 represents a cross-section ratio of copper. And, π1 represents a thickness of the core (a thickness of Invar), and π2 represents a thickness of copper layers (namely, the first heat transfer plate 20 and the second heat transfer plate 25) located on the surfaces. Further, η represents a penetration ratio of copper (cross-section ratio of copper in the holes of the core). The penetration ratio η of copper can be approximately obtained by, for example, in case of the radiator plate 1 on a plan view, dividing the maximum diameter of the hole 15 by a total value of a width of the strand 12 and the maximum diameter of the hole 15. For example, if the penetration ratio η is 0%, it shows that the radiator plate 1 is formed of CIC material. Further, the cross-section ratio of the core f1 and the cross-section ratio of copper f2 can be obtained by the following formulae 7 and 8.

f1=π1(1−η)/(π1+π2) Formula 7

f1+f2=1 Formula 8

Further, the heat expansion coefficient ρ in a direction of the plate surface (namely, a direction perpendicular to the plate thickness) can be obtained from a weighted average value of Young's modulus of Invar material constituting the core and Young's modulus of copper, and can be calculated by the following formula 9. Further, Young's modulus of Invar material is 142 GPa and Young's modulus of copper is 136 GPa. Here, in the formula 9, ρ1 represents a heat expansion coefficient of Invar material and ρ2 represents a heat expansion coefficient of copper.

ρ=ρ1·f1+ρ2·f2

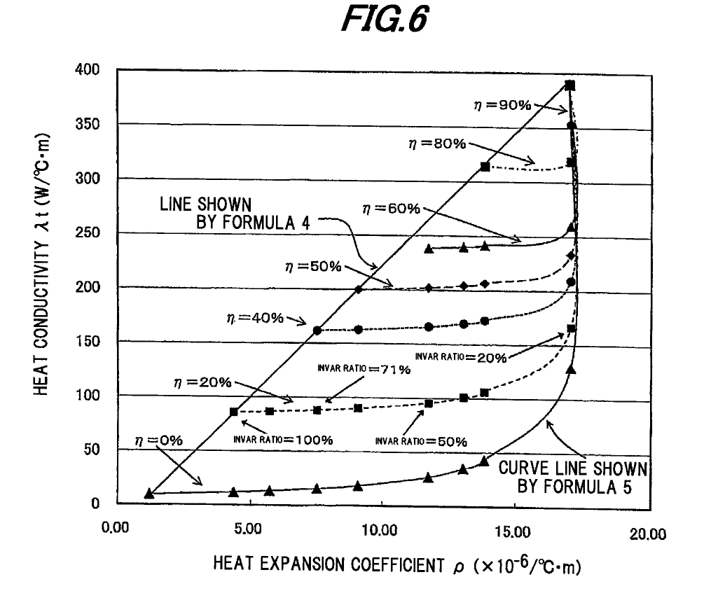

FIG. 6 is a graph schematically showing a relationship between a heat conductivity and a heat expansion coefficient of the radiator plate according to the first embodiment.

In FIG. 6, the penetration ratio is represented as “η” and simultaneously, the cross-section ratio of the core is represented as “Invar ratio”. And, each of markings on the curve line shows that the heat conductivity is changed according to the difference in the Invar ratio in each of the penetration ratios, and the heat conductivity is gradually decreased as the Invar ratio is increased. Further, in a region where the Invar ratio is increased more than 20% to 100%, in accordance with increase of the Invar ratio, the heat conductivity is gradually lowered.

Particularly, the Invar ratio is shown as 100%, 80%, 71%, 60%, 50%, 33%, 25%, 20% and 5% in that order, from a left side (where the heat conductivity is low) to a right side (where the heat conductivity is high) of FIG. 6 (In FIG. 6, as an example, positions where the Invar ratio is 100%, 71%, 50% and 20% are shown, of the markings of the Invar ratio on the curve line of η=20%). The decrease in the Invar ratio corresponds to the gradual decrease in the thickness of the core 10 (Invar material) to the plate thickness of the radiator plate 1 in accordance with the decrease in the Invar ratio.

And, for example, if the penetration ratio η is 20%, the heat conductivity is increased at a higher increasing rate in the Invar ratio of almost 25% to almost 20% than in the Invar ratio of almost 100% to almost 25%. And, when the Invar ratio becomes 20% to 5%, the heat conductivity is drastically increased. With regard to the change in the heat conductivity, any of the cases that the penetration ratio η is 0%, 40%, 50%, 60%, 80% and 90% show almost the same tendency.

FIG. 6 shows a result obtained by representing a relationship between the heat conductivity λt of the radiator plate and the heat expansion coefficient ρ from the formulae 4 to 9. The heat expansion coefficient of the lateral axis of FIG. 6 almost corresponds to the cross-sectional composition ratio. And, the heat conductivity of the vertical axis of FIG. 6 is changed according to the cross-sectional composition ratio. Further, the term “cross-sectional composition ratio” means both the cross-sectional ratio of Invar and the penetration ratio of copper.

In case of the CIC material formed by using a solid clad material, the heat conductivity in the plate surface direction is represented by the formula 4, and is linearly changed according to change of the cross-sectional composition ratio. On the other hand, the heat conductivity of the CIC material in the plate thickness direction is changed along a curve line represented by the formula 5. As is clear from referring to FIG. 6, in the CIC material, the heat conductivity in the plate thickness direction is drastically decreased when the Invar ratio becomes not less than 20%.

On the other hand, the radiator plate 1 using the core 10 used for the first embodiment is capable of adopting values that correspond to arbitrary points in a region encompassed with a straight line represented by the formula 4 and the curve line represented by the formula 5 according to a ratio between the penetration ratio and the cross-sectional composition ratio. The penetration ratio is changed according to the heat conductivity in the plate thickness direction. Namely, in a case that the penetration ratio is high, the radiator plate 1 having a higher heat conductivity can be obtained, in comparison with a case that the penetration ratio is low. In the embodiment, the penetration ratio and the cross-sectional composition ratio can be determined in a range up to a vicinity of the straight line represented by the formula 4 (namely, except for “on the straight line”), in the region encompassed with the straight line represented by the formula 4 and the curve line represented by the formula 5.

In the radiator plate 1 according to the first embodiment of the invention, in order to bring the heat conductivity in the plate thickness direction close to the heat conductivity in the plate surface direction, for example, a composition can be adopted that the penetration ratio η is within a range of almost 40% to 60%, and the Invar ratio is within a range of almost 50% to 70%, in the region encompassed with the straight line represented by the formula 4 and the curve line represented by the formula 5. For example, in the cross-section of the radiator plate 1 the thickness of the first heat transfer plate 20 and the thickness of the second heat transfer plate 25 are thinned, so that the heat conductivity in the plate thickness direction can be heightened.

Further, if the radiator plate is manufactured by using an expanded metal having hole axes inclined to the plate surface, materials constituting the first heat transfer plate 20 and the second heat transfer plate 25 do not sufficiently intrude into the holes. Consequently, in this case, the heat conductivity in the plate thickness direction is decreased by half in comparison with the radiator plate 1 according to the embodiment.

### Advantages of First Embodiment

In the radiator plate 1 according to the first embodiment of the invention, the core 10 includes a plurality of holes 15 having a fine diameter similar to the plate thickness of the core 10, the hole axes of the plural holes included in the core 10 are directed to a perpendicular direction to a surface of the radiator plate 1 and simultaneously, an opening ratio can be heightened, so that the first heat transfer plate 20 and the second heat transfer plate 25 can be appropriately joined to each other in the plural holes 15. Namely, the holes 15 used for the embodiment are formed, so that a region where materials constituting the first heat transfer plate 20 and the second heat transfer plate 25 are joined to each other can be increased and the penetration ratio can be increased. Due to this, according to the embodiment, the radiator plate 1 having a good heat conductivity in the plate thickness direction can be provided.

Namely, according to the radiator plate 1 of the embodiment, the cross-section ratios of the materials constituting the first heat transfer plate 20 and the second heat transfer plate 25 in the holes 15 are relatively high in comparison with the cross-section ratios of the core 10 in the cross-section of the radiator plate 1, so that the heat expansion coefficient in an in-plane direction can be lowered and simultaneously, the heat conductivity in a thickness direction can be heightened. Consequently, the radiator plate 1 according to the embodiment, for example, can be applied to a member of a semiconductor circuit on which semiconductor devices for supplying a large electric current are mounted.

And, the radiator plate 1 according to the embodiment can be made of Invar material and copper; Invar material and aluminum; or Invar material, copper and aluminum, so that it can be provided at a low price in comparison with a case of using copper and molybdenum (Mo), or copper and tungsten (W). And, the radiator plate 1 according to the embodiment can be used for applications that are required to have a low heat expansion coefficient and a high radiation performance in the plate thickness direction. For example, the radiator plate 1 according to the embodiment can be used as a radiator plate for a semiconductor device mainly formed of a material having a low linear expansion coefficient such as silicone (Si), silicone carbide (SiC) or the like (for example, the linear expansion coefficient of Si is low as almost 4×10⁻⁶ (1/K)), and the radiator plate 1 can prevent the semiconductor device from being separated from the radiator plate 1 due to heat stress caused by a difference between the linear expansion coefficient of the radiator plate 1 and the linear expansion coefficient of the semiconductor device.

Further, in the embodiment of the invention, values that correspond to arbitrary points in a region encompassed with the straight line represented by the formula 4 and the curve line represented by the formula 5 according to a ratio between the penetration ratio and the cross-sectional composition ratio can be adopted, and for example, the radiator plate 1 that has the heat conductivity and the heat expansion coefficient in the plate thickness direction adjacent to the straight line represented by the formula 4 can be formed. Due to this, the radiator plate 1 having properties equal to or surpassing a radiator plate formed of a low heat expansion coefficient material such as Cu—W, Cu—Mo, Low Expansion Copper (L-COP) or the like can be provided at a low price.

### Second Embodiment

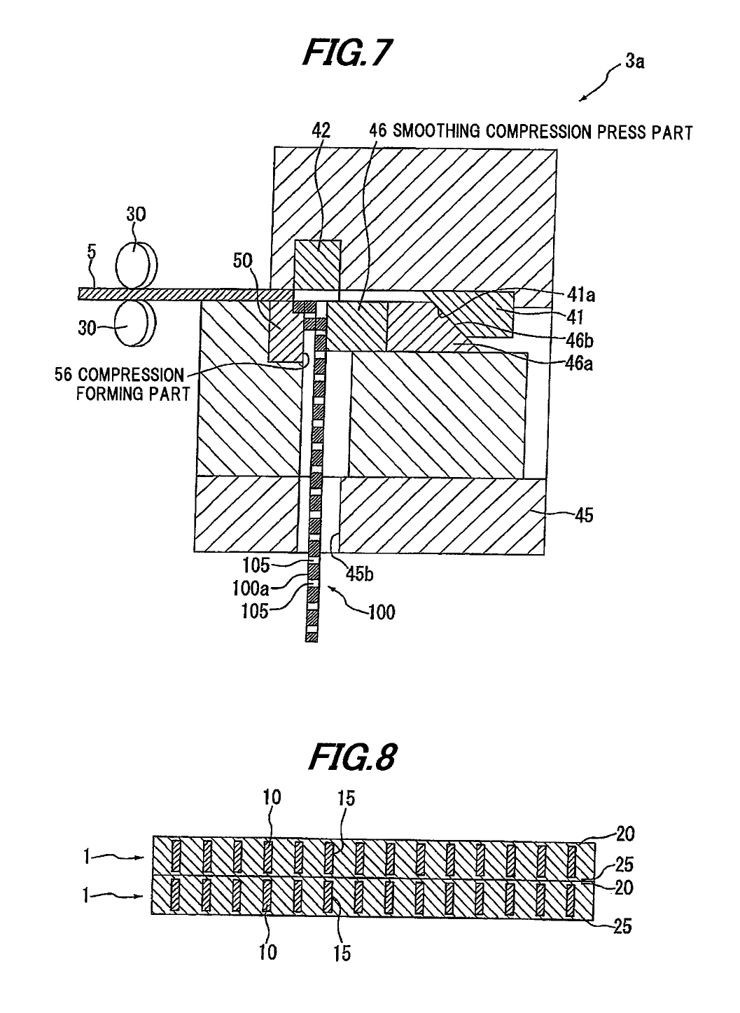

FIG. 7 is a cross-sectional view schematically showing a core material making equipment used for the second embodiment.

A method of making the core material 100 used for the second embodiment includes almost the same composition as the method of making the core material 100 used for the first embodiment, except that the bending work process is not included and the compression process is different, in comparison with the method of making the core material 100 used for the first embodiment. Consequently, a detail explanation will be omitted except for different points. Further, the core material 100 used for the second embodiment includes the same composition as the core material 100 used for the first embodiment, in a condition of “after the manufacturing”.

A core material production equipment 3a used for the second embodiment includes, as shown in FIG. 7, an obliquely feeding roll 30 for feeding a flat plate 5 to the core material production equipment 3a, a press forming part 42 and a lower cutter 50 for applying a cut work and a press work to the flat plate 5 which is fed, and a smoothing compression press 46 and a compression forming part 56 for applying a compression forming to a shaped article to which the cut work and the press work are applied.

First, the shaped article carried from the press forming part 42 and the lower cutter 50 is carried along a horizontal direction to an operation direction of the press forming part 42. And, the lower cutter 50 used for the embodiment further includes the compression forming part 56 in the side surface thereof, and a compression press is applied to the shaped article having oblique holes by the smoothing compression press 46 and the compression forming part 56.

As an example, an inclined surface 41a of a pressing part 41 included in a die set 40 presses an inclined surface 46b formed at an end part 46a of the smoothing compression press 46 according to an operation of the press forming part 42. And, the smoothing compression press 46 operates in a direction of the compression forming part 56 according to the pressing work. And, the smoothing compression press 46 applies the compression forming to the shaped article located between the smoothing compression press 46 and the lower cutter 50. By the application of the compression forming, the shaped article becomes the core material 100, and the core material 100 is discharged from an opening 45b of a die set bottom part 45 to the outside of the core material production equipment 3a.

In a modification of the second embodiment, a composition that does not include the pressing part 41 and the end part 46a can be also adopted. Namely, in the modification of the second embodiment, each of the press forming part 42 and the smoothing compression press 46 operates independently. For example, after the cutting process, the smoothing compression press 46 operates in a direction of the compression forming part 56. And, the smoothing compression press 46 applies the compression forming to the shaped article located between the smoothing compression press 46 and the compression forming part 56.

### Third Embodiment

FIG. 8 is a cross-sectional view schematically showing a multilayer radiator plate according to a third embodiment.

A multilayer radiator plate according to the third embodiment includes almost the same composition as the radiator plate 1 according to the first embodiment, except that the multilayer radiator plate has a structure that the radiator plates 1 according to the first embodiment are stacked. Consequently, a detail explanation will be omitted except for different points.

The multilayer radiator plate according to the third embodiment has a structure that two radiator plates 1 are stacked. Namely, in FIG. 8, one radiator plate 1 as a first radiator plate includes a core 10 as a first core having a core surface 10a as a first core surface and holes 15 as first holes whose hole axes 15a are directed to a direction along a normal direction of the core surface 10a; and a first heat transfer plate 20 joined to the core surface 10a and filled in the holes 15. And, another radiator plate 1 as a second radiator plate includes a core 10 as a second core having a core surface 10a as a second core surface and holes 15 as second holes whose hole axes 15a are directed to a direction along a normal direction of the core surface 10a; and a second heat transfer plate 25 joined to the core surface 10a and filled in the holes 15. And, the first heat transfer plate 20 and the second heat transfer plate 25 are joined to each other so that the multilayer radiator plate according to the third embodiment is formed.

The joining work of one radiator plate 1 and another radiator plate 1 is carried out by, for example, joining the first heat transfer plate 20 of the one radiator plate 1 to the second heat transfer plate 25 of the another radiator plate 1 by means of a cold welding, a diffusion welding, a joining work using a high temperature solder, or a joining work using a low temperature brazing material. Due to this, for example, a multilayer radiator plate having a thickness in the cross-section of more than 1.5 mm can be formed. Further, in a modification of the third embodiment, a multilayer radiator plate having a structure that at least three radiator plates 1 are stacked can be formed.

### Examples

As Examples of the invention, Fe-36Ni was used as a material constituting the core 10. And, the core material 100 is manufactured by a method of making a core material explained in the first embodiment. Subsequently, radiator plates according to Examples were manufactured by using the core material 100 manufactured and a method of making a radiator plate explained in the first embodiment. Both of the first heat transfer plate 20 and the second heat transfer plate 25 were formed of copper.

Particularly, values of a plate thickness (TI), a hole pitch (LW1), and a hole axis inclination of the core material 100 used for Examples, and values of a plate thickness (TIT), a penetration ratio of copper (η), a through hole pitch (LW), a ratio of through hole pitch to plate thickness (LW/TIT), an Invar ratio (I), a heat expansion coefficient, and a heat conductivity (λ) of the radiator plate according to Examples are shown in Table 1. Here, the through hole pitch (LW) is, for example, a distance between a hole axis 15a of one hole 15 of the radiator plate 1 and a hole axis 15a of another hole 15 adjacent to the one hole 15. Further, Table 1 shows values of the core material and the radiator plate according to Comparative Examples, and a thickness of copper sheet as a material constituting the first heat transfer plate 20 and the second heat transfer plate 25 (sheet of sheet coil for first heat transfer plate and sheet of sheet coil for second heat transfer plate) as a copper plate thickness.

TABLE 1

| | | | | | | | Comp | Comp | Comp | Comp | Comp |
|---|---|---|---|---|---|---|---|---|---|---|---|
| Item | | | Ex 1 | Ex 2 | Ex 3 | Ex 4 | Ex 1 | Ex 2 | Ex 3 | Ex 4 | Ex 5 |
| Copper plate thickness | | (TCu₀(mm)) | 0.15 | 0.5 | 0.06 | 0.1 | 0.13 | 0.4 | 0.5 | — | — |
| Core | Plate thickness | TI (mm) | 0.5 | 1 | 0.2 | 0.2 | 0.5 | 1 | 1 | — | — |
| material | Hole pitch | LW1 (mm) | 1.1 | 1.2 | 0.44 | 0.24 | 1.5 | 1.6 | 20 | — | — |
| | Hole axis inclination | (°) | 90 | 90 | 90 | 90 | 33 | 29 | 66 | — | — |
| Heat | Plate thickness | TIT (mm) | 0.27 | 0.8 | 0.11 | 0.16 | 0.45 | 0.72 | 0.8 | 1 | 1 |
| transfer | Penetration ratio | η(%) | 40 | 55 | 40 | 55 | 22 | 23 | 44 | — | — |
| plate | Through hole pitch | LW (mm) | 24 | 22 | 1.0 | 0.4 | 8.5 | 3.5 | 39.0 | — | — |
| | Ratio of through hole | LW/TIT | 9.1 | 27 | 8.9 | 27 | 19.0 | 4.8 | 48.8 | — | — |
| | pitch to plate thickness | | | | | | | | | | |
| | Invar ratio | I (%) | 50 | 31 | 50 | 31 | 50 | 31 | 30 | 50 | 33 |
| | Heat expansion | (×10⁶/° C. m) | 8.9 | 11.9 | 8.9 | 11.9 | 8.9 | 11.9 | 120 | 8.4 | 11.0 |
| | coefficient | | | | | | | | | | |
| | Heat conductivity (in | (W/° C. m) | 163 | 221 | 163 | 221 | 95 | 101 | 180 | 21 | 31 |
| | plate thickness direction) | | | | | | | | | | |

| | | | | | | | | |
|---|---|---|---|---|---|---|---|---|
| Remarks | Fine holes | Fine holes | Thinned | Thinned | Fine holes | Fine holes | Thinned | CIC material |

| | |
|---|---|
| Utilization of fine pore metal | Utilization of rolling |
| | and smoothing of |
| | expanded metal |

(Notes)
Ex: Example, Comp Ex: Comparative Example

Further, in Examples (Examples 1 to 4), the plate thickness of the core material 100 was set to 0.2 mm to 1 mm. And, the hole pitch was set to 0.24 mm to 1.2 mm. Each of the hole axes of holes of the core materials 100 according to Examples 1 to 4 was perpendicular to the plate surface. And, in each of Examples 1 to 4, copper sheets (sheet pulled out from sheet coil for first heat transfer plate and sheet pulled out from sheet coil for second heat transfer plate) having a thickness as the Invar ratio becomes a predetermined value were laminated on the upper and lower surfaces of the core material 100, and the core material 100 laminated by the copper sheets was rolled. Further, the copper sheets have thicknesses as shown in Table 1. The rolling work was carried out under the condition that an intermetallic compound does not generate between the core material 100 and the copper sheets.

Following the rolling work, a diffusion heat treatment was carried out at almost 600 degrees C. Due to this, a joining state was obtained that materials constituting the core material 100 having fine holes and the copper sheets diffused between the material 100 and the copper sheets mutually, but the intermetallic compound did not generate. Further, the rolling work was carried out by a degree of processing of almost 50%. Due to this, in each of Examples 1 to 4, radiator sheets were manufactured. And, the radiator sheets according to Examples 1 to 4 were cut so as to have a predetermined size, so that radiator plates according to Examples 1 to 4 were manufactured.

On the other hand, the radiator plates according to Comparative Examples 1 to 3 used a core that was formed of the same material as the core used for each of Examples 1 to 4, and was obtained by that an expanded metal having fine holes to which only the cutting work and press work were applied was rolled so as to have a smooth surface. This is due to the fact that it is difficult for the conventional method of manufacturing the expanded metal to manufacture the expanded metal having smaller holes in comparison with the plate thickness. The expanded metal having fine holes did not pass through the bending work process that was carried out in Examples, so that the hole axes were inclined to the plate surface. And, the radiator plates according to Comparative Examples 4 and 5 were formed by using a core having no holes. Namely, the radiator plates according to Comparative Examples 4 and 5 are formed of the CIC material.

And, each of the radiator plates according to Examples 1 to 4 and Comparative Examples 1 to 5 was evaluated with regard to the heat conductivity in the thickness direction and the ratio of through hole pitch to plate thickness. Further, in any of Examples and Comparative Examples, the radiator plates were manufactured so as to have the Invar ratios of 50% and almost 30% as typical cases.

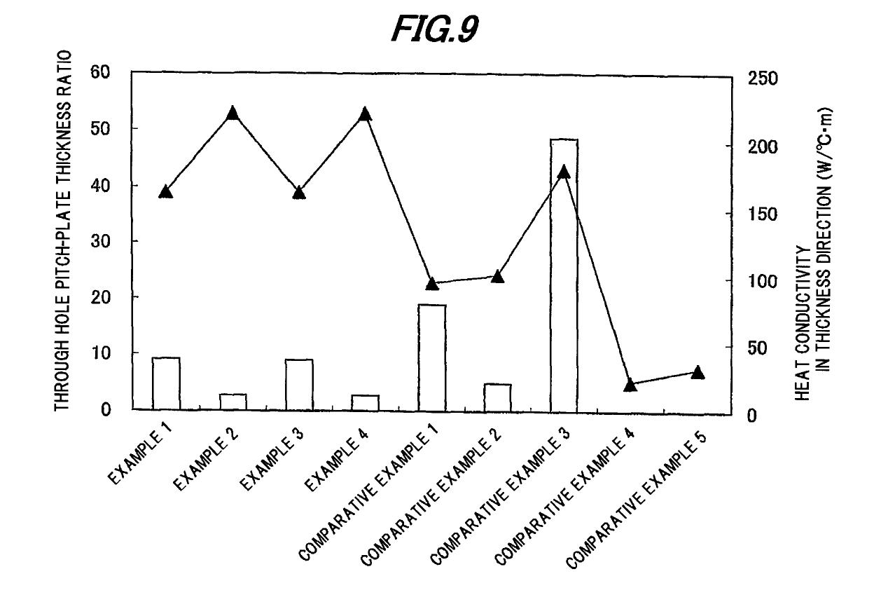

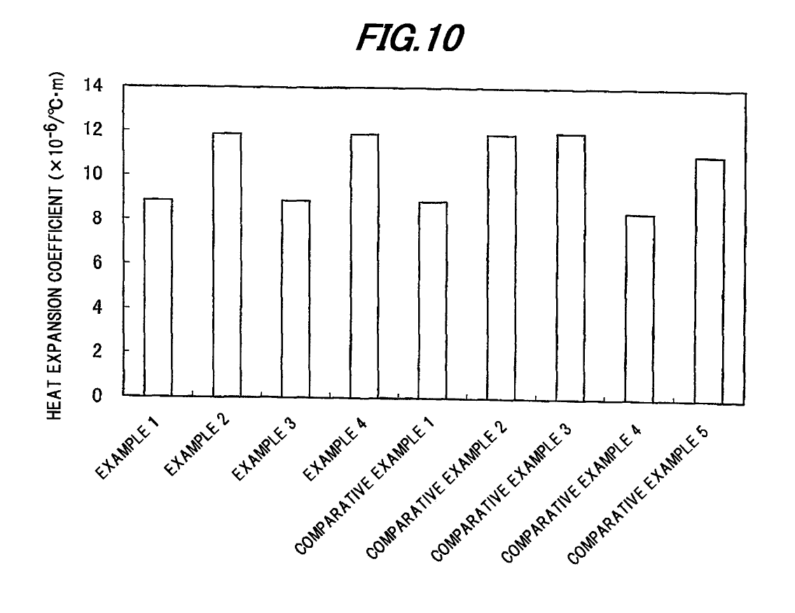

FIG. 9 is a graph schematically showing the heat conductivity in the plate thickness direction and the ratio of through hole pitch to plate thickness of the radiator plate according to Examples and Comparative Examples. And, FIG. 10 is a graph schematically showing the heat expansion coefficient of the radiator plate according to Examples and Comparative Examples.

As shown in FIG. 10, in the radiator plates according to Examples 1 to 4, the heat expansion coefficient was ranged within 8.9 to 11.9×10⁻⁶ (/° C.·m), and in the radiator plates according to Comparative Examples 1 to 5, the heat expansion coefficient was ranged within 8.4 to 12.0×10⁻⁶ (W/° C.·m).

And, as shown in FIG. 9, in the radiator plate according to Comparative Example 4, the heat conductivity in the thickness (plate thickness) direction was 21 (W/° C.·m), and in the radiator plate according to Comparative Example 5, the heat conductivity in the thickness (plate thickness) direction was 31 (W/° C.·m). In view of the fact that the heat conductivity in the in-plane direction of the radiator plate according to Comparative Example 4 was 200 (W/° C.·m) although it is not shown in Table 1, and the heat conductivity in the in-plane direction of the radiator plate according to Comparative Example 5 was 260 (W/° C.·m), the heat conductivity in the thickness direction of Comparative Examples 4 and 5 was one digit smaller than that in the in-plane direction.

Here, each of the through hole pitches of Examples 1 and 2 was 2.4 mm and 2.2 mm, and the pitches of Example 3 and 4 was set to 1 mm and 0.4 mm. And, the Invar ratio of Examples 1 and 3 was 50%, and the Invar ratio of Examples 2 and 4 was 31%. The heat conductivity in the thickness direction of the radiator plates according to Examples 1 and 3 was 163 (W/° C.·m), and that of the radiator plates according to Examples 2 and 4 was 221 (W/° C.·m). It was shown that in the radiator plates according to Examples 1 to 4, the heat conductivity in the thickness direction was comparable to the heat conductivity (for example, 200 to 260 (W/° C.·m)) in the in-plane direction of the CIC material (for example, Comparative Examples 4 and 5).

And, the heat conductivity in the thickness direction of the radiator plates according to Comparative Examples 1 and 2 was 95 to 101 (W/° C.·m), and it was improved than that of the radiator plates according to Comparative Examples 4 and 5. However, in comparison with the radiator plates according to Examples 1 to 4, the radiator plates according to Examples 1 to 4 showed the higher heat conductivity than the radiator plates according to Comparative Examples 1 and 2. This is probably due to the fact that the holes included in the core according to Comparative Examples 1 and 2 are inclined to the plate surface so that it is difficult to improve the heat conductivity in the thickness direction.

And, the heat conductivity of radiator plate according to Comparative Example 3 was 180 (W/° C.·m), but the through hole pitch was 39 mm, consequently, it is difficult to realize a radiator plate having fine holes. Namely, the radiator plates according to Examples 1 to 4 has a structure that the through hole pitch is 0.4 to 2.4 mm, a plurality of fine holes are formed in the core at an extremely short distance and coppers having a high heat conductivity is filled in each of the plural holes. Due to this, for example, in case that the radiator plate is cut out to a size adjusted to a semiconductor device of an integrated circuit (IC), the following difference is caused between the radiator plate according to Comparative Example 3 and the radiator plate s according to Examples 1 to 4.

Namely, in case of the radiator plate according to Comparative Example 3, when it is cut out, either a radiator plate whose large portion is formed of a heat transfer plate or a radiator plate whose large portion is formed of a core is cut out. On the other hand, in case of the radiator plates according to Examples 1 to 4, they have the through hole pitch of a narrow pitch described above, so that a radiator plate including a core formed of Invar material and a heat transfer plate formed of copper at an appropriate ratio can be obtained, even if the radiator plate is cut out. Further, the core included in the radiator plate according to Comparative Example 3 has the hole axes inclined to the plate surface, and consequently, if the through hole pitch is tried to be narrowed to an extent almost equal to the radiator plates according to Examples 1 to 4, the opening ratio becomes simultaneously small, so that the radiator plate has a limitation to an enhancement of the heat conductivity in the thickness direction.

### Fourth Embodiment

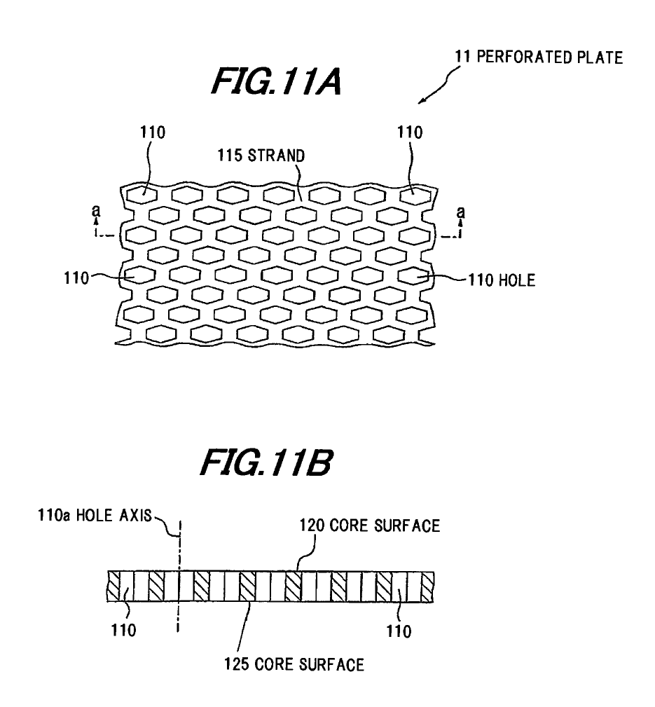

FIG. 11A is a plan view schematically showing a part of perforated plate according to a fourth embodiment, and FIG. 11B is a cross-sectional view taken along the line A-A in FIG. 11A.

Structure of Perforated Plate 11

A perforated plate 11 according to a fourth embodiment of the invention includes a plurality of strands 115, a plurality of holes 110 formed by being encompassed with the plural strands 115. The plural strands 115 forming one hole 110 are sequentially and integrally formed. And, a core surface 120 and a core surface 125 located oppositely to the core surface 120 are formed by the surfaces of the plural strands. Further, the holes 110 used for the fourth embodiment are formed so as to have hole axes 110a thereof are perpendicular to the core surface 120 and the core surface 125. Namely, axis directions of the hole axes 110a correspond to normal lines of the core surface 120 and the core surface 125.

The plural holes 110 included in the perforated plate 11 are formed so as to have an arrangement that a pattern is repeated where one hole 110 is encompassed with other six holes 110 adjacent to the one hole 110. Particularly, the plural holes 110 are formed in a honeycomb shape. The plural holes 110 are respectively formed in almost a hexagonal shape (or a tortoiseshell shape) on a plan view. Further, in a modification of the embodiment, the plural holes 110 can also be formed in a diamond shape on a plan view respectively. And, the perforated plate 11 is formed of a metal material such as iron (Fe), aluminum (Al), an alloy material including at least one selected from the metal material or an alloy steel such as SUS.

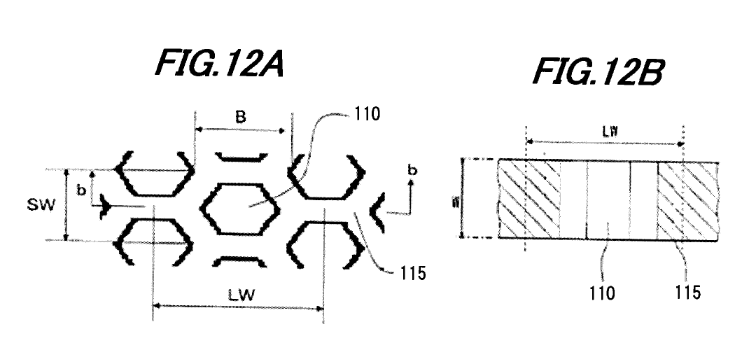

FIG. 12A is a partial enlarged view schematically showing a hole of the perforated plate according to the fourth embodiment, and FIG. 12B is a cross-sectional view taken along the line b-b in FIG. 12A.

In FIG. 12A, a distance between one hole 110 and another hole adjacent to the one hole 110 (hereinafter referred to as “hole pitch of first direction” or “hole pitch of direction along a width of cutting edge 152” described below) is defined as LW. And, a plate thickness of the perforated plate 11 is defined as W. In this case, in the perforated plate 11 according to the embodiment, a value of LW is formed so as to be not less than that of W. Further, in FIG. 12B, T represents a plate thickness of a flat plate which is a raw material of the perforated plate 11. And, a hole pitch of second direction, namely, a hole pitch of a direction perpendicular to the first direction (direction along a width of cutting edge 152) is defined as SW. Further, B represents a bond length.

Here, the perforated plate 11 according to the embodiment has a shape that, for example, a value of LW is not less than a value of W. For example, the perforated plate 11 can be formed so as to have a ratio (LW/W) between LW and W of not more than 3, preferably not less than 1 and not more than 3. Further, the perforated plate 11 can also be formed to have the value of ratio (LW/W) of more than 3. And, as an example, a flat plate having a plate thickness T of not more than 1 mm can be used, in order that the plate thickness T is reduced to a value being not more than a size of the hole 110.

Method of Making Perforated Plate 11

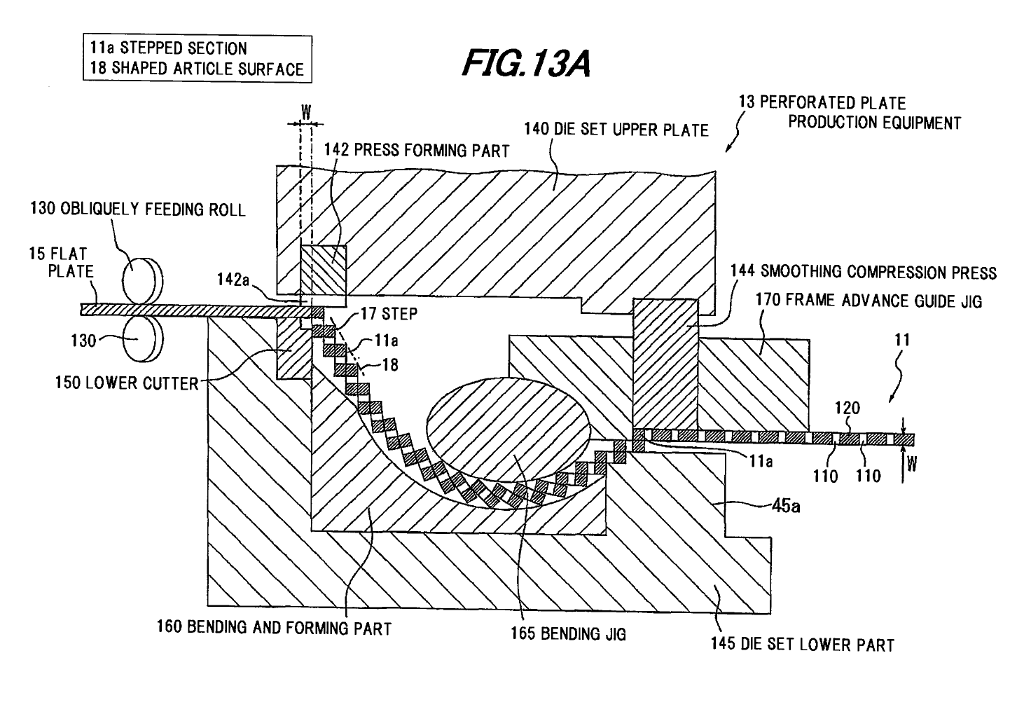

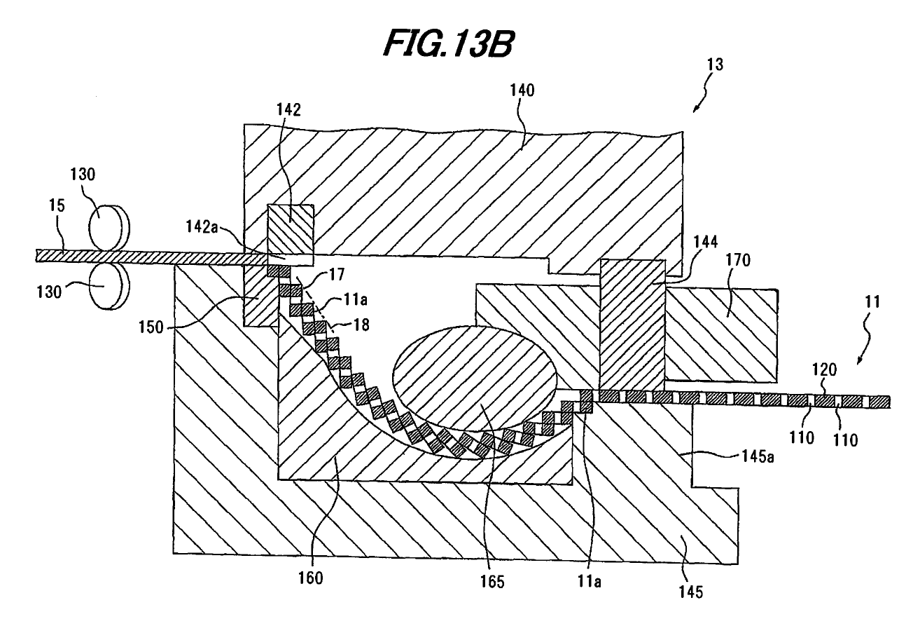

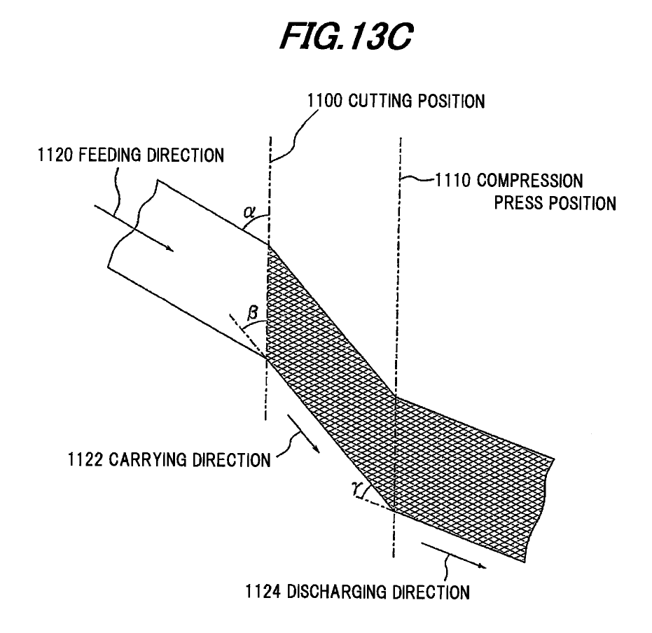

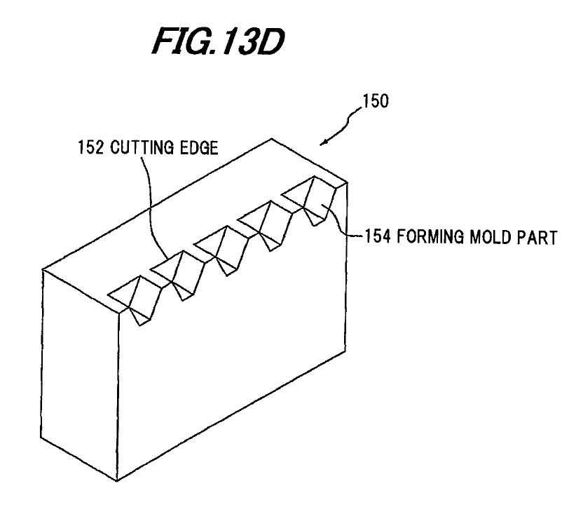

FIG. 13A is a cross-sectional view schematically showing a top dead point position of press in a method of making the perforated plate according to the fourth embodiment, FIG. 13B is a cross-sectional view schematically showing a bottom dead point position of press in a method of making the perforated plate according to the fourth embodiment, FIG. 13C is an explanatory view schematically showing a flow of a raw material used for making the perforated plate according to the fourth embodiment, and FIG. 13D is a perspective view schematically showing a lower cutter used for making the perforated plate according to the fourth embodiment.

Particularly, FIG. 13A shows an outline at a top dead point position and just before a press forming process. And, FIG. 13B shows an outline at a bottom dead point position, a shaped article just after the press forming process, and the perforated plate 11 manufactured by passing through a compression process.

A perforated plate production equipment 13 used for making the perforated plate 11 according to the embodiment includes, as shown in FIG. 13A, an obliquely feeding roll 130 for feeding a flat plate 15 which is a material of the perforated plate 11 to the perforated plate production equipment 13, a press forming part 142 and a lower cutter 150 for applying a cut work and a press work to the flat plate 15 which is fed, a bending and forming part 160 and a bending jig 165 for applying a bending work to the shaped article to which the cut work and the press work are applied, a smoothing compression press 144 for applying a compression forming to the shaped article to which the bending work is applied, and a frame advance guide jig 170 for feeding the shaped article to which the bending work is applied to the smoothing compression press 144. Further, the press forming part 142 and the smoothing compression press 44 are held in a die set upper plate 140 and the lower cutter 150 and the bending and forming part 160 are disposed in a die set lower part 145.

In the embodiment, the press forming part 142 and smoothing compression press 144 operate in a normal direction (namely, in a vertical direction) of a surface of the flat plate 15 fed to the perforated plate production equipment 13 according to an operation of the die set upper plate 140. Particularly, the press forming part 142 used for the embodiment moves only in a vertical direction, and does not move in a feeding direction of the flat plate 15 to the perforated plate production equipment 13 and in a perpendicular direction (a normal direction of a plane of paper in FIG. 13A) to both of the vertical direction and the feeding direction.

The perforated plate production equipment 13 intermittently presses the die set upper plate 140 to the die set lower part 145 at high speed so as to apply a cut work, a press work and a smoothing compression work to the flat plate 15, and manufacture the perforated plate 11 (for example, fine pore plate) according to the embodiment. Hereinafter, the embodiment will be explained in concrete. Further, in the following explanation, the perforated plate 11 according to the embodiment may be referred to as “fine pore metal”.

Flat Plate Feeding Process

First, the flat plate 15 (for example, a solid flat plate coil) which is a material of the perforated plate 11 is inclined to a longitudinal direction of the lower cutter 150 via the obliquely feeding roll 130, and is intermittently fed to the press forming part 142 and the lower cutter 150. Particularly, as shown in FIG. 13C, the longitudinal direction of the flat plate 15 is inclined to a cutting position 1100 described below by an angle α where a plurality of cuts are formed by the press forming part 142 and the lower cutter 150, and the flat plate 15 is fed to the perforated plate production equipment 13. Namely, the flat plate 15 is fed to the perforated plate production equipment 13 along a feeding direction 1120 which is inclined to the cutting position 1100 by an angle α (FIG. 13C). Further, the flat plate 15 is fed to the perforated plate production equipment 13 at a feeding stroke synchronized with a cycle (hereinafter referred to as “cutting cycle”) when the press forming part 142 is pressed to one surface of the flat plate 15.

Here, the angle α is set as an angle that is calculated from the following formula 11.

$$α = {tan}^{- 1} \frac{2 W}{LW} \qquad Formula 1$$

Further, a speed (a feeding speed) for feeding the flat plate 15 to the perforated plate production equipment 13 is set as a speed defined by the following formula per one stroke of the press. Namely, in the embodiment, the feeding speed is synchronized with the cutting cycle. Further, the term “press” means that the press forming part 142 is pressed to the lower cutter 150 so as to cut a part of the flat plate 15, and when the press forming part 142 is pressed to the lower cutter 150, the feeding speed of the flat plate 15 to the perforated plate production equipment 13 becomes zero, and when the press forming part 142 is separated from the lower cutter 150, the feeding speed of the flat plate 15 to the perforated plate production equipment 13 becomes a speed defined by the following formula 2.

$$feeding speed = \sqrt{\frac{{W}^{2} + {LW}^{2}}{4}} \qquad Formula 2$$

Further, in the formulae 1 and 2, “W” represents a feeding width per one stroke of the flat plate 15 in case of feeding the flat plate 15 to the perforated plate production equipment 13. Namely, as shown in FIG. 13A, a cut is formed in the flat plate 15 with respect to each “W”, and “W” corresponds to a step size of the flat plate 15.

Cutting Process and Press Work Process

Next, the flat plate 15 fed between the press forming part 142 and the lower cutter 150 is supported at one surface thereof by the lower cutter 150, and is pressed from a side of another surface thereof by the press forming part 142 (FIG. 13B). By this, a plurality of cuts are formed in the flat plate 15 (cutting process). And, at the same time of the formation of the cuts, the press forming part 142 applies a press work to the plural cuts so as to form shaped articles having a plurality of oblique holes from the plural cuts (press work process). Tangent lines at the corner parts of a plurality of steps 17 of the shaped article form a shaped article surface 18. Further, in the embodiment, the term “oblique hole” means a hole whose hole axis is inclined to a surface of the shaped article. And, the term “at the same time” means “in a series” or “successively”.

And, in a modification of the embodiment, the cutting process and press work process can be carried out as follows. Namely, first, in the cutting process a plurality of cuts are formed in the flat plate 15. And at the time point when the plural cuts are formed, the manufacturing process is once stopped (stopping process). Subsequently, the press work process can be carried out. And, in another modification of the embodiment, the cutting process can be a process that includes a multiple-stage cutting operation.

Particularly, the press forming part 142 used for the embodiment includes a wave edge 142a having a corrugated shape. On the other hand, the lower cutter 150, as shown in FIG. 13D, includes a cutting edge 152 for forming the plural cuts to the flat plate 15 and a forming mold part 154 disposed adjacent to the cutting edge 152 and having an almost corrugated shape, for applying the press work to each of the plural cuts. Namely, an upper end of the lower cutter 150 has a concavo-convex shape that the cutting edge 152 and the forming mold part 154 are successively disposed.

The cutting process and press work process will be explained in more detail. First, the flat plate 15 fed between the press forming part 142 and the lower cutter 150 is formed so as to have intermittent and plural cuts by the wave edge 142a of the press forming part 142 and the cutting edge 152 of the lower cutter 150 (for example, the cuts having a staggered shape are formed in the flat plate 15). Namely, the wave edge 142a is pressed to the cutting edge 152 so that the plural cuts are formed in the flat plate 15. And, a precise press work (for example, a precise wave shape work) are applied to each of the plural cuts by the press forming part 142 and a precise forming mold part which is the forming mold part 154. Namely, the wave edge 142a is pressed to the forming mold part 154 so that an oblique hole is formed in the staggered shape from each of the plural cuts. By this, a shaped article having the oblique holes which are arranged at a short pitch to a plate thickness of the flat plate 15. As an example, a ratio of the plate thickness of the flat plate 15 to the pitch can be set to 2 to 3, and in this case, the pitch can be brought close to the plate thickness. The shaped article where the oblique holes are formed is carried from the press forming part 142 and the lower cutter 150 to an oblique direction to an operation direction of the press forming part 142. Further, a hole pitch of a direction along a width of the cutting edge 152 and a hole pitch of a direction perpendicular to the direction along the width of the cutting edge 152 are almost the same as the pitch of the concavity and convexity of the cutting edge 152 in case of just after the cutting process, and are different from the pitch of the concavity and convexity of the cutting edge 152 in case of after the press process.

The lower cutter 150 used for the embodiment has the cutting edge 152 and the forming mold part 154 so that the cutting and press works are simultaneously applied to the flat plate 15. After the cutting process and the press work process, the flat plate 15 becomes the shaped article having the plural oblique holes. The shaped article, as shown in FIG. 13C, is fed to the bending and forming part 160 along a carrying direction 1122. Namely, in the embodiment, a feeding direction 1120 of the flat plate 15 to the perforated plate production equipment 13 is changed to the carrying direction 1122 which is a different direction from the feeding direction 1120 at the cutting position 1100.

Here, as shown in FIG. 13C, the carrying direction 1122 is inclined to the cutting position 1100 by an angle β. The angle β is defined by the following formula.

$$β = {tan}^{- 1} \frac{SW}{LW} \qquad Formula 3$$

Bending Work Process

Next, the shaped article is passed through between the bending and forming part 160 and the bending jig 165 so as to apply a bending work to the shaped article and correct the hole axis direction of the oblique hole (bending work process). Namely, the bending work is applied to the shaped article which passes through the cutting process and the press work process by the bending and forming part 160 and the bending jig 165 so as to arrange the hole axes of the plural oblique holes in one direction. Particularly, the hole axes of the plural oblique holes are arranged in a direction along an operation direction of a smoothing compression press 144 described below. Namely, the hole axes of the plural oblique holes are gradually rotated to the carrying direction 1122 as the shaped article is pressed to the bending and forming part 160 by the bending jig 165 and simultaneously is carried along the carrying direction 1122. And, the shaped article where the hole axes of the oblique holes are rotated by almost 90 degrees to the hole axes just after the cutting process and the press work process is fed to the smoothing compression press 144.

Further, the shaped article in a state that directions of the hole axes of the oblique holes are equal to each other is fed to the smoothing compression press 144 by a frame advance guide jig 170. Namely, the shaped article is fed to the smoothing compression press 144 frame by frame. Here, the term “frame” means a unit where the plural oblique holes of the shaped article are linearly arranged in a line.

Compression Process

Next, a compression forming is applied to the shaped article fed to the smoothing compression press 144 by the frame advance guide jig 170 frame by frame, by the smoothing compression press 144 which vertically moves in a direction along the hole axes of the holes of the shaped article, namely, along a direction horizontal to the hole axes (compression process, FIG. 13B). The compression forming is applied to a stepped section 11a of the shaped article which is carried between the smoothing compression press 144 and a receiving part 145a. By this, the perforated plate 11 having a plate thickness of “W” is manufactured. Further, in the embodiment, the plate thickness of “W” of the perforated plate 11 corresponds to a feeding width in case of feeding the flat plate 15 to the press forming part 142 and the lower cutter 150.

Subsequently, the perforated plate 11 where a plurality of holes 110 having hole axes perpendicular to the core surface 120 are formed is discharged to the outside of the perforated plate production equipment 13 along the discharging direction 1124 (FIG. 13C). The compression forming is applied to the stepped section 11d, so that the perforated plate 11 discharged from the perforated plate production equipment 13 is formed so as to have the core surface 120 and core surface 125 which are flat. Further, if the perforated plate 11 is discharged from the compression press position 1110 that is a position where the smoothing compression press 144 applies the compression forming to the shaped article to the outside of the perforated plate production equipment 13, the discharging direction 1124 is changed to the compression press position 1110 by an angle γ. Further, the angle γ is changed according to a quality of material of the flat plate 15, a shape of the plural holes 110 or the like.

Here, since the shaped article having the oblique holes is compressed by the compression process, it is preferable that a material constituting the shaped article, namely, a material constituting the flat plate 15 is selected from materials being easily deformable due to the compression. And, since the stepped section 11d in the shaped article is compressed so as to be reduced in the thickness up to almost ½ of the thickness before the compression by the compression process, it is preferable to use a material having a ductibility enough to prevent an occurrence of breakage or the like, even if compressed up to the thickness. For example, it is preferable to use the above-mentioned metal material or the alloy material.

Modifications

In a modification of the method of making the perforated plate 11 according to the fourth embodiment, the press forming part 142 can be operated not only in a vertical direction, but also in a normal direction of a plane of paper in FIG. 13A (a lateral direction) with half pitch shift, every time when the press forming part 142 is pressed to the lower cutter 150. In this case, both of the press forming part 142 and the lower cutter 150 are reciprocated in a direction perpendicular to the operation direction of the press forming part 142. Namely, the press work is carried out with half pitch shift of the press forming part 142 to the lower cutter 150 and with half pitch shift of the lower cutter 150 to the press forming part 142. And, a structure of the lower cutter 150 is formed to have a shape capable of corresponding to the operation in a lateral direction of the press forming part 142, so that directions of the plural cuts formed in the flat plate 15 can be adjusted to the direction of the shaped article.

And, the plate thickness of the perforated plate 11 according to the fourth embodiment is compressed to “W” in the compression process, but the plate thickness of the perforated plate 11 after the compression process can be formed to be not more than “2 W”, as long as the compression is applied to the stepped section 11d. In this case, the hole axes are also perpendicular to the plate surface, and the smoothness of the surface of perforated plate 11 can be enhanced in comparison with a case that the compression process is not passed through.

### Advantages of Fourth Embodiment

According to a method of making a perforated plate of the embodiment, the cutting process and the press process being a precise press process are simultaneously applied to the flat plate 15 fed to the perforated plate production equipment 13, and after that, the bending work and the compression process are applied, so that the perforated plate 11 (fine perforated plate, namely, fine pore metal) that is smooth and has the holes 110 whose hole axes 110a are perpendicular to the core surface 120 and the core surface 125, whose hole diameter is smaller than the plate thickness and whose opening ratio is large can be provided. And, since the plural holes 110 are formed by the cutting process and the press work process, scissel is not produced different from a punching metal, so that a production yield can be improved and all of the flat plate 15 can be fabricated to the perforated plate 11.

Particularly, the lower cutter 150 used for the embodiment has the cutting edge 152 and the forming mold part 154, and when the press forming part 142 is pressed to the lower cutter 150, the cutting edge 152 forms the cuts of a staggered shape to the flat plate 15 and simultaneously, the forming mold part 154 applies a precise wave shape forming to the cuts, so that the shaped article that has the oblique holes with a pitch shorter than the plate thickness of the flat plate 15 can be formed. And, the bending work is applied to the shaped article and the hole axes of the oblique holes are rotated, and after that, the compression forming is applied to the shaped article to which the bending work is applied, so that the perforated plate 11 that has the holes whose hole axes are perpendicular to the plate surface can be manufactured.

And, according to a method of making a perforated plate of the embodiment, the angle α at which the flat plate 15 is fed to the perforated plate production equipment 13 is defined as the formula 1 and simultaneously, the speed per one stroke at which the flat plate 15 is fed to the perforated plate production equipment 13 is defined as the formula 2, so that a press forming of a net-like shape can be carried out and the processes can be realized at a high speed and with a high degree of accuracy only by that the press forming part 142 is operated in a vertical direction without being operated in a lateral direction.

The perforated plate 11 according to the embodiment can be applied to a light filter, a fluid filter and the like that have a large opening ratio.

### Fifth Embodiment

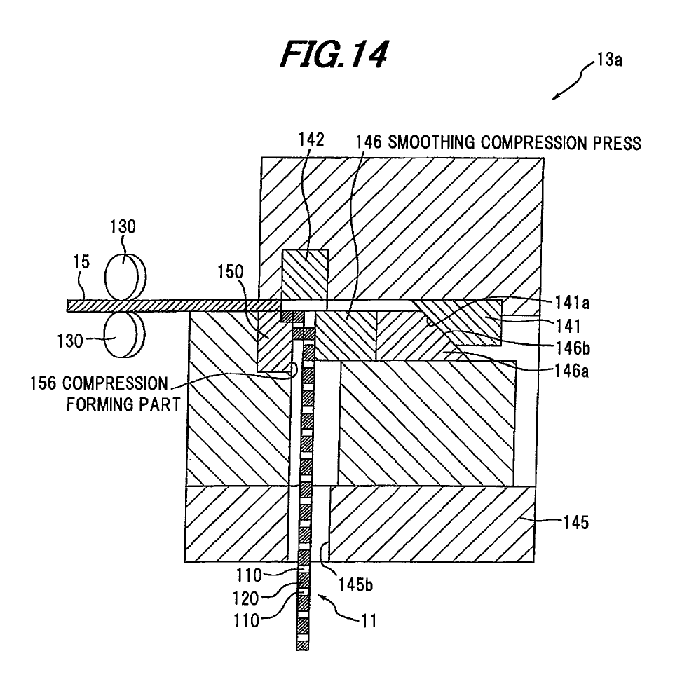

FIG. 14 is a cross-sectional view schematically showing a perforated plate making equipment used for the fifth embodiment.

A method of making the perforated plate 11 according to the fifth embodiment includes almost the same composition as the method of making the perforated plate 11 according to the fourth embodiment, except that the bending work process is not included and the compression process is different, in comparison with the method of making the perforated plate 11 according to the fourth embodiment. Consequently, a detail explanation will be omitted except for different points.

A perforated plate production equipment 13a used for the fifth embodiment includes, as shown in FIG. 14, an obliquely feeding roll 130 for feeding a flat plate 15 to the perforated plate production equipment 13a, a press forming part 142 and a lower cutter 150 for applying a cut work and a press work to the flat plate 15 which is fed, and a smoothing compression press 146 and a compression forming part 156 for applying a compression forming to a shaped article to which the cut work and the press work are applied.

First, the shaped article carried from the press forming part 142 and the lower cutter 150 is carried along a horizontal direction to an operation direction of the press forming part 142. And, the lower cutter 150 used for the embodiment further includes the compression forming part 156 in the side surface thereof, and a compression press is applied to the shaped article having oblique holes by the smoothing compression press 146 and the compression forming part 156.

As an example, an inclined surface 141a of a pressing part 141 included in a die set 140 presses an inclined surface 146b formed at an end part 146a of the smoothing compression press 146 according to an operation of the press forming part 142. And, the smoothing compression press 146 operates in a direction of the compression forming part 156 according to the pressing work. And, the smoothing compression press 146 applies the compression forming to the shaped article located between the smoothing compression press 146 and the lower cutter 150. By the application of the compression forming, the shaped article becomes the perforated plate 11, and the perforated plate 11 is discharged from an opening 145b of a die set bottom part 145 to the outside of the perforated plate production equipment 13a.

In a modification of the fifth embodiment, a composition that does not include the pressing part 141 and the end part 146a can be also adopted. Namely, in the modification of the fifth embodiment, each of the press forming part 142 and the smoothing compression press 146 operates independently. For example, after the cutting process, the smoothing compression press 146 operates in a direction of the compression forming part 156. And, the smoothing compression press 146 applies the compression forming to the shaped article located between the smoothing compression press 146 and the compression forming part 156.

### Example 5

In Example 5, a perforated plate having a shape set forth in Japanese Industrial Standards (JIS)-32 (refer to JISG3351) was manufactured by the perforated plate production equipment 13 used for the fourth embodiment according to the invention. As a material of the perforated plate, SUS 304 material was used. Further, the perforated plate was formed so as to have a plate thickness of “W” that was equal to the feeding width to the perforated plate production equipment 13.

And, as Comparative Example 6, a perforated plate (an expanded metal) having a shape set forth in JIS-32 was manufactured. The expanded metal according to Comparative Example 6 was manufactured without being passed through the bending process and the compression process. Further, as Comparative Example 7, an expanded metal was manufactured, the expanded metal having undergone a rolling work and obtained by that the rolling work was applied to the perforated plate according to Comparative Example 6.

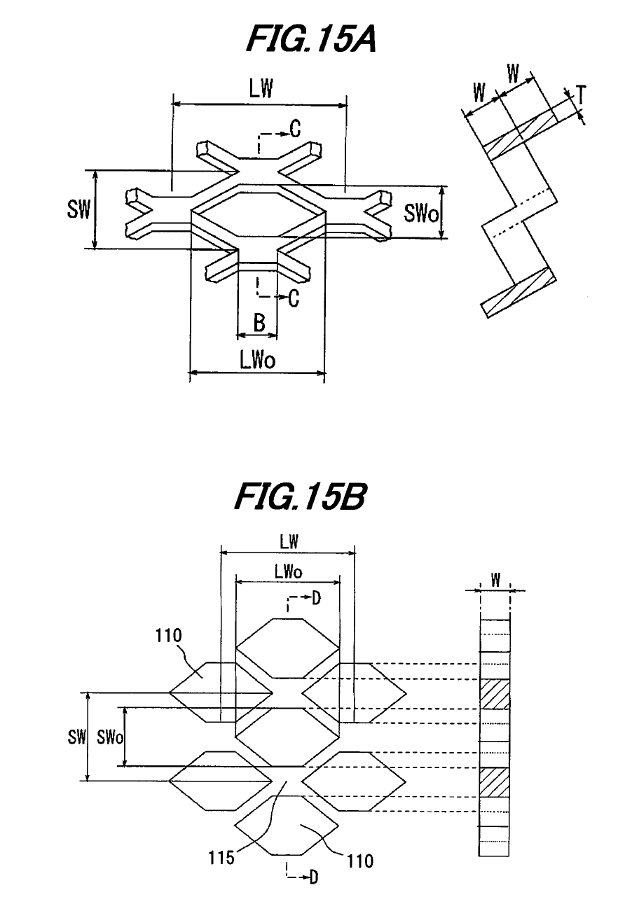

FIG. 15A is an explanatory view schematically showing each site of the shaped article before the cutting process (the process of forming cuts) and the press work process in Example 5 and Examples 6 to 11 described below, and FIG. 15B is an explanatory view schematically showing each site of the shaped article after the cutting process (process of forming cuts) and the press work process in Example 5 and Examples 6 to 11 described below. Further, a drawing located to the right side of FIG. 15A is a cross-sectional view taken along the line C-C in FIG. 15A and a drawing located to the right side of FIG. 15B is a cross-sectional view taken along the line D-D in FIG. 15B.

In FIGS. 5A and 5B, the term “T” means a plate thickness of the flat plate before the compression forming. The term “W” means a plate thickness of the flat plate after the compression forming and a feeding width of the flat plate to the perforated plate production equipment 13. In Examples, the hole axes of the holes 110 are formed so as to be perpendicular to a surface of the fine pore metal and the compression forming is applied to the shaped article in the manufacturing process, so that the plate thickness T is approximately double the plate thickness To before the press work. And, the term “SW” means a hole pitch of the hole 110 in a direction perpendicular to a direction along the width of cutting edge 152, and the term “LW” means a hole pitch of the hole 110 in a direction along the width of cutting edge 152. Further, the fine pore metals according to Examples have a fine pitch that the strand 115 is thicker and the holes 110 are smaller than those of the conventional expanded metal.

And, Table 2 shows a dimension of each site of the shaped articles after the cutting process and the press work process according to Examples 5 to 11.

TABLE 2

| | | | | | | | | | LW/ |
|---|---|---|---|---|---|---|---|---|---|
| | | SW | SW₀ | LW | LW₀ | T | W | B | W |
| Ex 5 | JIS-32 | 12 | 9.3 | 30.5 | 23.5 | 1.6 | 2 | 2 | 15.3 |
| Ex 6 | JIS-14 | 34 | 18.6 | 135 | 81.9 | 8 | 9 | 30 | 15.0 |
| Ex 7 | small holes | 2.8 | 1.1 | 2.0 | 0.9 | 0.5 | 1 | 0.5 | 2.0 |
| Ex 8 | fine pore A | 1.4 | 0.8 | 1 | 0.44 | 0.5 | 0.5 | 0.42 | 2 |
| Ex 9 | fine pore B | 1.21 | 0.6 | 2 | 1.4 | 0.5 | 1 | 0.6 | 2 |
| Ex 10 | A thickened | 0.56 | 0.32 | 0.4 | 0.18 | 0.2 | 0.2 | 0.17 | 2 |
| Ex 11 | B thickened | 0.54 | 0.12 | 0.4 | 0.28 | 0.1 | 0.2 | 0.12 | 2 |

(Notes)
Ex: Example

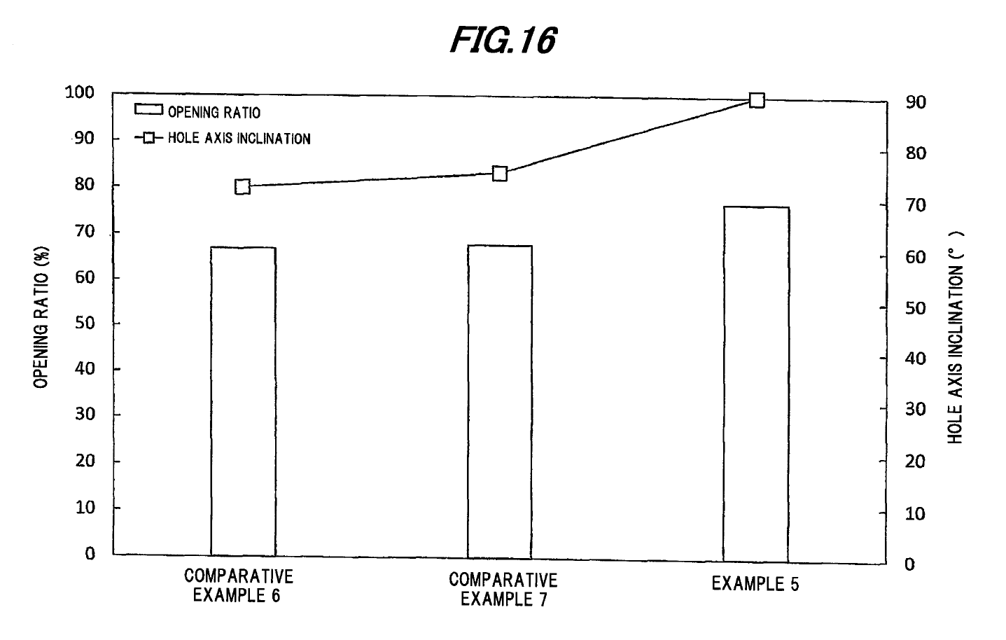

FIG. 16 is a graph showing a compassion result of an opening ratio and a hole axis inclination between a perforated plate according to Example 5 and expanded metals according to Comparative Examples 6 and 7.

JIS-32 Shape

Cases of the perforated plate having a shape of JIS-32 (Example 5), and expanded metals (Comparative Examples 6 and 7) will be explained. In these cases, an inclination of the hole axis (a hole axis inclination) of the expanded metal according to Comparative Example 6 was 72 degrees. And, the hole axis inclination of the expanded metal according to Comparative Example 7 which has undergone the rolling work was 75 degrees. On the other hand, the hole axis inclination of the perforated plate according to Example 5 was 90 degrees. Next, an opening ratio of the expanded metal according to Comparative Example 6 was 67%, and the opening ratio of the expanded metal according to Comparative Example 7 which has undergone the rolling work was 68%. On the other hand, the opening ratio of the perforated plate according to Example 5 was 77%. Further, the term of “opening ratio” means a penetration probability of the hole on a plan view, and is calculated from the following formula in case of the expanded metal according to Comparative Example 6.

Opening ratio=SW₀×(LW₀+B)/SW/LW×100

### Example 6

In Example 6, a perforated plate having a shape set forth in JIS-14 was manufactured by the perforated plate production equipment 13 used for the fourth embodiment according to the invention. As a material of the perforated plate, SUS 304 material was used. The other manufacturing method was carried out similarly to Example 5.

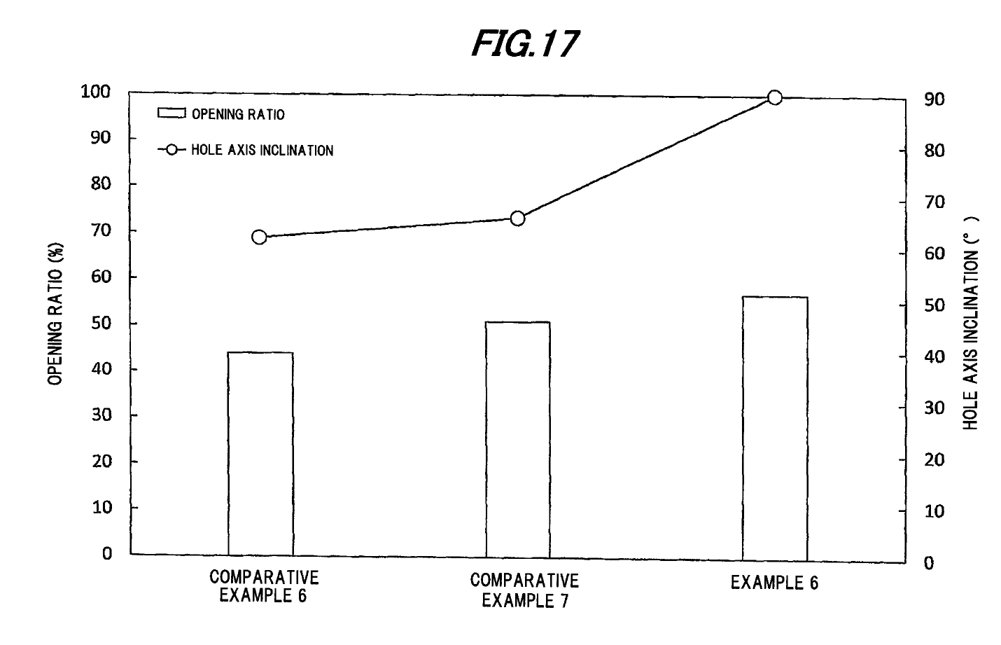

FIG. 17 is a graph showing a compassion result of an opening ratio and a hole axis inclination between a perforated plate according to Example 6 and expanded metals according to Comparative Examples 8 and 9.

JIS-14 Shape

Cases of the perforated plate having a shape of JIS-14 (Example 6), and expanded metals (Comparative Examples 8 and 9) will be explained. In these cases, an inclination of the hole axis (a hole axis inclination) of the expanded metal according to Comparative Example 8 was 62 degrees. And, the hole axis inclination of the expanded metal according to Comparative Example 9 which has undergone the rolling work was 66 degrees. On the other hand, the hole axis inclination of the perforated plate according to Example 6 was 90 degrees. Next, an opening ratio of the expanded metal according to Comparative Example 8 was 44%, and the opening ratio of the expanded metal according to Comparative Example 9 which has undergone the rolling work was 51%. On the other hand, the opening ratio of the perforated plate according to Example 6 was 57%.

From the results of Examples 5 and 6, it was shown that in cases of Examples 5 and 6, the hole axes of the holes included in the perforated plate are perpendicular to the plate surface of the perforated plate, and the opening ratio of each of Examples 5 and 6 becomes larger than each of Comparative Examples corresponding to the Examples 5 and 6 respectively. And, from the results of Examples 5 and 6, it was shown that in case that the ratio of LW/W is almost 15, for example, in case that the ratio of LW/W is not less than 10 and not more than 100, the opening ratio in Examples 5 and 6 can be increased.

### Examples 7 to 11

In Example 7, a perforated plate (fine pore metal: small holes) having the holes of a small diameter that LW is 2 mm was manufactured by the perforated plate production equipment 13 used for the fourth embodiment according to the invention. As a material of the perforated plate, SUS 304 material was used. Further, a thickness of flat plate as a material of the perforated plate was 0.5 t, and the feeding width W of the flat plate to the perforated plate production equipment 13 was 2 mm. The other manufacturing method was carried out similarly to Example 5. And, similarly to Example 7, a perforated plate having LW of 1 mm (Example 8: fine pore metal: fine pore A), a perforated plate having LW of 2 mm (Example 9: fine pore metal: fine pore B), a perforated plate having LW of 0.32 mm and W of 0.2 mm (Example 10: fine pore metal: A thickened), and a perforated plate having LW of 0.12 mm and W of 0.2 mm (Example 11: fine pore metal: B thickened) were manufactured respectively.

As Reference Example 1, a perforated plate was manufactured without the bending work process and the compression process, in the manufacturing process of the perforated plate according to Example 7. And, as Reference Example 2, a perforated plate which has undergone a rolling work was manufactured by applying the rolling work to the perforated plate according to Reference Example 1.

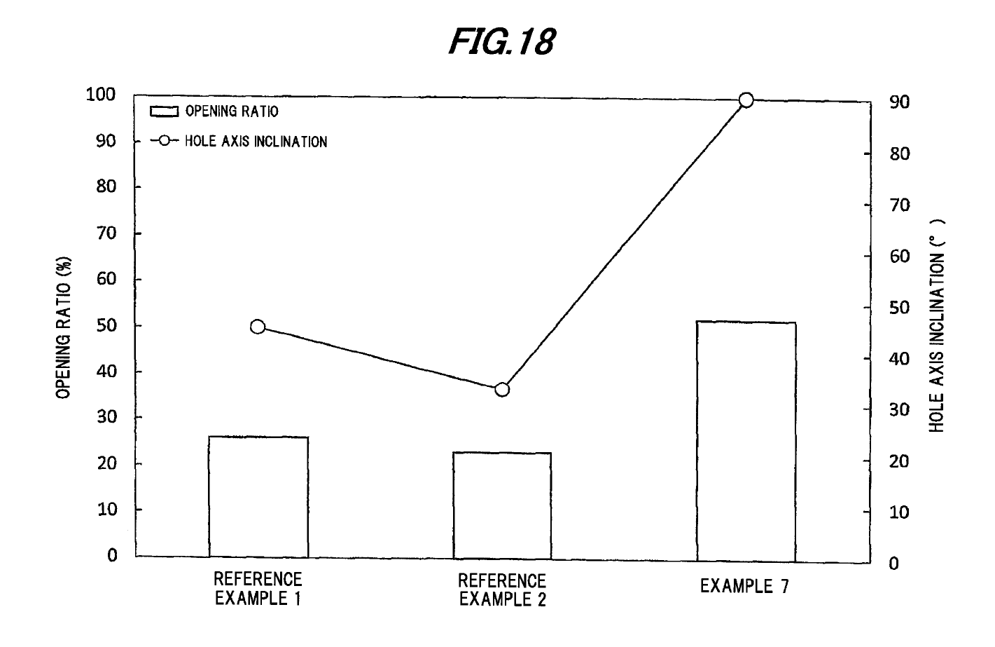

FIG. 18 is a graph showing a compassion result of an opening ratio and a hole axis inclination between a perforated plate according to Example 7 and expanded metals according to Reference Examples 1 and 2.

Results of the fine pore metal (Example 7) and Reference Examples 1 and 2 will be explained. In these cases, an inclination of the hole axis (a hole axis inclination) of the perforated plate according to Reference Example 1 was 45 degrees, and, the hole axis inclination of the perforated plate according to Reference Example 2 which has undergone the rolling work was 33 degrees. On the other hand, the hole axis inclination of the fine pore metal according to Example 7 was 90 degrees. Next, an opening ratio of the perforated plate according to Reference Example 1 was 26%, and the opening ratio of the perforated plate according to Reference Example 2 which has undergone the rolling work was 23%. On the other hand, the opening ratio of the fine pore metal according to Example 7 was 65%.

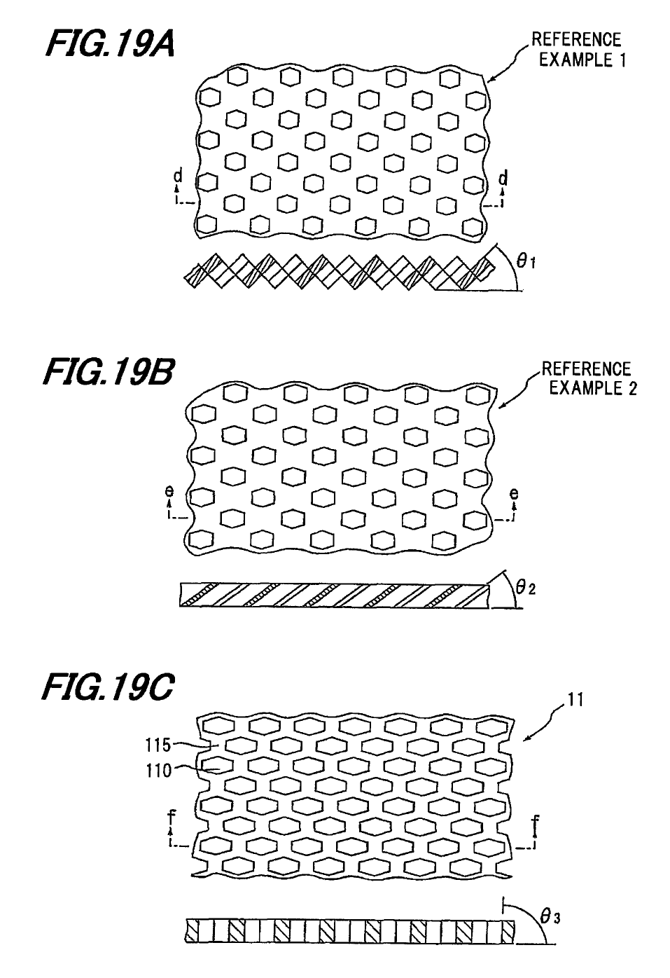

FIG. 19A is an explanatory view schematically showing a perforated plate according to Reference Example 1, FIG. 19B is an explanatory view schematically showing a perforated plate according to Reference Example 2 and FIG. 19C is an explanatory view schematically showing a perforated plate having a structure of a fine pore metal according to Example 7.

The perforated plate according to Reference Example 1 has the opening ratio of 26%, and an angle θ1 of the hole axis shown in a cross-sectional view taken along the line d-d in FIG. 19A was 45 degrees. And, the perforated plate according to Reference Example 2 has the opening ratio of 23%, and an angle θ2 of the hole axis shown in a cross-sectional view taken along the line e-e in FIG. 19B was 33 degrees. On the other hand, the fine pore metal according to Example 7 has the opening ratio of 65%, and an angle θ3 of the hole axis shown in a cross-sectional view taken along the line f-f in FIG. 19C was 90 degrees. The opening ratio of the fine pore metal of Example 7 was 2.5 times higher than those of the perforated plates according to Reference Examples 1 and 2.

From the result of Example 7, it was shown that even if the perforated plate is a small hole type perforated plate having the LW/W of almost 2, a fine pore metal which has hole axes perpendicular to the plate surface and a large opening ratio could be manufactured.

### Example 8

And, a fine pore metal was manufactured similarly to Example 7, except for changing a material of the fine more metal to the Invar material such as a 42 alloy or the like and the super Invar material. As a result, a fine pore metal as a smooth fine pore type perforated plate having a large opening ratio similarly to Example 7 could be manufactured.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A radiator plate, comprising:
a core having core surfaces and holes whose hole axes are directed in a direction along a normal direction of the core surface; and
heat transfer plates joined to the core surfaces and filled in the holes.

2. The radiator plate according to claim 1, wherein the holes are formed by being enclosed with a plurality of strands,
the core surfaces include a first core surface formed by one surface of the plural strands and a second core surface formed by another surface of the plural strands and opposed to the first core surface, and
the hole axes are directed in directions along normal directions of the first core surface and the second core surface.

3. The radiator plate according to claim 2, wherein the heat transfer plates include a first heat transfer plate disposed so as to contact the first core surface and a second heat transfer plate disposed so as to contact the second core surface, and
the first heat transfer plate and the second heat transfer plate are connected to each other via the first heat transfer plate filled in the holes and the second heat transfer plate filled in the holes.

4. The radiator plate according to claim 3, wherein the core has a plurality of the holes, and
a ratio of a distance between one hole of the plural holes and another hole adjacent to the one hole to a plate thickness of the heat transfer plate is less than 10.

5. The radiator plate according to claim 4, wherein the plural holes have total areas on a plan view whose occupation ratio to a surface area of the heat transfer plate is not less than 10% and not more than 90%.

6. The radiator plate according to claim 5, wherein the core is formed of a material having a heat expansion coefficient lower than the heat transfer plate, and
the heat transfer plate is formed of a material having a thermal conductivity coefficient higher than the core.

7. The radiator plate according to claim 6, wherein the core is formed of an Invar material or a super Invar material, and
the heat transfer plate is formed of a material selected from the group consisting of copper (Cu), aluminum (Al), a copper alloy and an aluminum alloy.

8. A multilayer radiator plate, comprising:
a first radiator plate including a first core having first core surfaces and first holes whose hole axes are directed in a direction along a normal direction of the first core surface and first heat transfer plates joined to the first core surfaces and filled in the first holes;
a second radiator plate including a second core having second core surfaces and second holes whose hole axes are directed in a direction along a normal direction of the second core surface and second heat transfer plates joined to the second core surfaces and filled in the second holes; and
the first radiator plate and the second radiator plate are joined to each other.

9. A method of making a radiator plate, comprising:
preparing a core material having core surfaces and holes whose hole axes are directed in a direction along a normal direction of the core surface; and
joining heat transfer plates to the surfaces of the core material.

10. The method of making a radiator plate according to claim 9, wherein the preparing of the core material comprises:
forming a plurality of cuts in a flat plate by pressing a press forming part to the flat plate intermittently-fed, in a direction of a lower cutter supporting the flat plate at the one surface of the flat plate, from another surface side of the flat plate;
forming a shaped article having a plurality of oblique holes and a flat surface by applying a press forming to the plural cuts; and
applying a compression forming to the shaped article along a direction of the hole axes of the plural oblique holes of the shaped article so as to form the core surface having the plural holes whose hole axes are perpendicular to a direction of the flat surface of the shaped article and being perpendicular to a direction to which the hole axes face.

11. The method of making a radiator plate according to claim 10, wherein the lower cutter has cutting edges for forming the plural cuts and a forming mold part disposed adjacent to the cutting edges for applying a press work to the plural cuts,
the plural cuts are formed by that the press forming part is pressed toward the cutting edges, and
the shaped article are formed together in forming the cuts by that the press forming part is pressed toward the forming mold part.

12. The method of making a radiator plate according to claim 11, further comprising:
correcting a direction of the hole axes by applying a bending work to the shaped article; and
forming the radiator plate from the shaped article to which the bending work is applied.

13. The method of making a radiator plate according to claim 12, wherein the plural cuts are formed to the flat plate that is fed in a state of being inclined to a longitudinal direction of the lower edges, and simultaneously at a feeding stroke synchronized with a cycle when the press forming part is pressed to the flat plate.

14. The method of making a radiator plate according to claim 13, wherein the heat transfer plates are joined to each other by using a cold rolling clad process or a warm rolling clad process.

15. A method of making a perforated plate, comprising:
forming a plurality of cuts in a flat plate by pressing a press forming part to the flat plate intermittently-fed, in a direction of a lower cutter supporting the flat plate at the one surface of the flat plate, from another surface side of the flat plate;
forming a shaped article having a plurality of oblique holes and a flat surface by applying a press forming to the plural cuts; and
applying a compression forming to the shaped article along a direction of the hole axes of the plural oblique holes of the shaped article so as to form the perforated plate having the plural holes whose hole axes are perpendicular to a direction of the flat surface of the shaped article and being perpendicular to a direction to which the hole axes face.

16. The method of making a perforated plate according to claim 15, wherein the lower cutter has cutting edges for forming the plural cuts and a forming mold part disposed adjacent to the cutting edges for applying a press work to the plural cuts,
the plural cuts are formed by that the press forming part is pressed toward the cutting edges, and
the shaped article are formed together in forming the cuts by that the press forming part is pressed toward the forming mold part.

17. The method of making a perforated plate according to claim 16, further comprising:
applying a bending work to the shaped article; and
forming the perforated plate from the shaped article to which the bending work is applied.

18. The method of making a perforated plate according to claim 17, wherein the plural cuts are formed to the flat plate that is fed in a state of being inclined to a longitudinal direction of the lower edges, and simultaneously at a feeding stroke synchronized with a cycle when the press forming part is pressed to the flat plate.

19. The method of making a perforated plate according to claim 18, wherein where a distance between one hole of the plural holes and another hole adjacent to the one hole is defined as LW and a plate thickness of the perforated plate is defined as W, the perforated plate is formed so as to have a value of the LW which is not less than a value of the W.

20. A method of making a perforated plate, comprising:
forming a plurality of cuts in a flat plate by pressing a press forming part to the flat plate intermittently-fed, in a direction of a lower cutter supporting the flat plate at the one surface of the flat plate, from another surface side of the flat plate;
forming a shaped article having a plurality of oblique holes and a flat surface by applying a press forming to the plural cuts; and
applying a compression forming to the shaped article along a direction of the hole axes of the plural oblique holes of the shaped article by pressing a smoothing compression press part to the shaped article from a direction perpendicular to the pressing direction of the press forming part so as to form the perforated plate having the plural holes whose hole axes are perpendicular to a direction of the flat surface of the shaped article and being perpendicular to a direction to which the hole axes face.

21. The method of making a perforated plate according to claim 20, wherein the smoothing compression press part is pressed to a side surface of the lower cutter.

22. A perforated plate, comprising:
a plurality of strands;
a plurality of holes formed by being encompassed with the plural strands; and
core surfaces formed by surfaces of the plural strands, wherein hole axes of the plural holes are perpendicular to the core surfaces.

23. The perforated plate according to claim 22, wherein where a distance between one hole of the plural holes and another hole adjacent to the one hole is defined as LW and a plate thickness of the perforated plate is defined as W, a value of the LW is not less than a value of the W.
